(19) United States
(12) Patent Application Publication
(10) Pub. No.: US 2024/0365649 A1
(43) Pub. Date: Oct. 31, 2024

(54) DATA TRANSMISSION METHODS, ELECTRONIC TAG AND ELECTRONIC DEVICE

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Dan GUO, Beijing (CN); Ke LIU, Beijing (CN); Fei FANG, Beijing (CN); Jingjing XU, Beijing (CN); Ling SHI, Beijing (CN); Puyu QI, Beijing (CN); Changchang LIU, Beijing (CN)

(21) Appl. No.: 18/254,968

(22) PCT Filed: May 31, 2022
(86) PCT No.: PCT/CN2022/096459

§ 371 Date: May 30, 2023

(51) Int. Cl. H10K 59/80; H10K 59/131; H10K 59/35

(52) U.S. Cl. CPC H10K 59/8792; H10K 59/131; H10K 59/353

(57) ABSTRACT

A display panel includes a substrate and a plurality of first sub-pixels and a plurality of light-shielding portions which are both located in a functional device configuration region. At least some first sub-pixels each include a first pixel circuit and a first light-emitting device. The plurality of first light-shielding portions are arranged on a side of a plurality of first light-emitting devices away from the substrate at intervals. An orthographic projection of a first portion, whose orthographic projection is located outside an orthographic projection of a first electrode of the first light-emitting device on the substrate, of the first pixel circuit on the substrate is located within an orthographic projection of a first light-shielding portion of the plurality of light-shielding portions on the substrate.

### CROSS-REFERENCE TO RELATED APPLICATION

The application is a national phase entry under 35 USC 371 of International Patent Application No. PCT/CN2022/096459 filed on May 31, 2022, which is incorporated herein by reference in its entirety.

### TECHNICAL FIELD

The present disclosure relates to the field of display technologies, and in particular, to a display panel and a display apparatus.

### BACKGROUND

With the rapid development of display technologies, display apparatuses have gradually come throughout people's lives. Due to advantages such as self-luminescence, low power consumption, wide viewing angle, quick response, high contrast and flexible display, organic light-emitting diodes (OLEDs) are widely used in mobile phones, televisions, notebook computers and other intelligent products.

### SUMMARY

In an aspect, a display panel is provided. The display panel has a functional device configuration region. The display panel includes a substrate, a plurality of first sub-pixels and a plurality of first light-shielding portions. The plurality of first sub-pixels are disposed on the substrate, and located in the functional device configuration region. At least some of the plurality of first sub-pixels each include a first pixel circuit and a first light-emitting device. The first light-emitting device includes a first electrode. The first electrode is electrically connected with the first pixel circuit. An orthographic projection of a portion of the first pixel circuit on the substrate is located outside an orthographic projection of the first electrode on the substrate.

The plurality of first light-shielding parts are arranged on a side of a plurality of the first light-emitting devices of the at least some of the plurality of first sub-pixels away from the substrate at intervals, and located in the functional device configuration region. Each first light-shielding portion is provided with a plurality of first opening regions. Each first opening region corresponds to a single first light-emitting device of the plurality of first light-emitting devices, and a light-emitting region of the single first light-emitting device is located in the first opening region. An orthographic projection of a first portion of a first pixel circuit electrically connected with a first electrode of the single first light-emitting device on the substrate is located within an orthographic projection of the first light-shielding portion on the substrate. The first portion is a portion, whose orthographic projection on the substrate is located outside the orthographic projection of the first electrode on the substrate, of the first pixel circuit.

In some embodiments, the display panel includes a plurality of first pixel units disposed in the functional device configuration region. Each first pixel unit includes multiple first sub-pixels of the first sub-pixels. The plurality of first opening regions of each first slight-shielding portion correspond to multiple first sub-pixels of a same first pixel unit of the plurality of first pixel units in a one-to-one manner.

In some embodiments, for multiple first sub-pixels located within an outer border of a same first light-shielding portion, a distance between centers of two first sub-pixels that are adjacent to each other in a setting direction is a first distance. In the setting direction, a distance between centers of two adjacent first sub-pixels, which are respectively located within outer borders of two adjacent first light-shielding portions, is a second distance. The first distance is less than the second distance.

In some embodiments, the plurality of first sub-pixels include a plurality of red sub-pixels, a plurality of first green sub-pixels, a plurality of second green sub-pixels and a plurality of blue sub-pixels.

The plurality of red sub-pixels and the plurality of first green sub-pixels are alternately arranged in a first oblique direction, and the plurality of red sub-pixels and the plurality of second green sub-pixels are alternately arranged in a second oblique direction. The plurality of blue sub-pixels and the plurality of second green sub-pixels are alternately arranged in the first oblique direction, and the plurality of blue sub-pixels and the plurality of first green sub-pixels are alternately arranged in the second oblique direction. The plurality of first green sub-pixels and the plurality of second green sub-pixels are alternately arranged in a first direction; and the plurality of red sub-pixels and the plurality of blue sub-pixels are alternately arranged in a second direction. The first direction is perpendicular to the second direction, the first oblique direction intersects the second oblique direction, both the first oblique direction and the second oblique direction intersect each of the first direction and the second direction; or the first direction is perpendicular to the second direction, the first oblique direction intersects the second oblique direction, both the first oblique direction and the second oblique direction intersect each of the first direction and the second direction, and the setting direction is any one of the first direction, the second direction, the first oblique direction and the second oblique direction.

In some other embodiments, the display panel includes plurality of first pixel units. Each first pixel unit includes a red sub-pixel, a first green sub-pixel, a second green sub-pixel and a blue sub-pixel that are adjacent to each other. For a same first pixel unit, a red sub-pixel and a blue sub-pixel are arranged in the second direction, and a first green sub-pixel and a second green sub-pixel are arranged in the first direction. An outer border of an orthographic projection of a first light-shielding portion of the plurality of first light-shielding portions on the substrate is in a shape of an approximate rhombus.

In some embodiments, the plurality of first light-shielding portions are arranged in a plurality of rows and a plurality of columns. Each row includes multiple first light-shielding portions arranged in a first direction, and each column includes multiple first light-shielding portions arranged in a second direction. The first direction is perpendicular to the second direction.

In some embodiments, the display panel further includes an electrode layer. The electrode layer is disposed between first electrodes of the at least some of the plurality of first sub-pixels and the plurality of first light-shielding portions. A portion, located within the functional device configuration region, of the electrode layer is provided with a plurality of second opening regions. At least a portion of orthographic projections of the plurality of second opening regions on the substrate are located in a region between orthographic projections of the plurality of first light-shielding portions on the substrate.

In some embodiments, the plurality of first light-shielding portions are arranged in a plurality of rows and a plurality of columns. Each row includes multiple first light-shielding portions arranged in a first direction, and each column includes multiple first light-shielding portions arranged in a second direction. The first direction is perpendicular to the second direction. Two adjacent first light-shielding portions in the first direction are provided therebetween with a second opening region; and/or two adjacent first light-shielding portions in the second direction are provided therebetween with a second opening region.

In some embodiments, multiple first light-shielding portions in a row are arranged to be staggered with multiple first light-shielding portions in another row adjacent thereto, and multiple first light-shielding portions in a column are arranged to be staggered with multiple first light-shielding portions in another column adjacent thereto.

In some embodiments, a second opening is in a shape of an approximate circle or an approximate ellipse.

In some embodiments, the display substrate further has a main display region. The main display region at least partially surrounds the functional device configuration region. The display panel further includes plurality of second sub-pixels and a second light-shielding portion. The plurality of second sub-pixels are disposed on the substrate, and located in the main display region. Each second sub-pixel includes a second pixel circuit and a second light-emitting device. At least some of a plurality of second light-emitting devices of the plurality of second sub-pixels each include a third electrode. The third electrode is electrically connected with a second pixel circuit of a plurality of second pixel circuits of the plurality of second sub-pixels. An orthographic projection of a portion of the second pixel circuit on the substrate is located outside an orthographic projection of the third electrode on the substrate.

The second light-shielding portion is disposed on a side of the plurality of second sub-pixels away from the substrate, and located in the main display region. The second light-shielding portion includes a plurality of third opening regions. Each third opening region corresponds to a single second light-emitting device of the plurality of second light-emitting devices, and a light-emitting region of the single second light-emitting device is located in the third opening region. Orthographic projections of second portions of a plurality of second pixel circuits electrically connected to third electrodes of the at least some of the plurality of second devices on the substrate are located within an orthographic projection of the second light-shielding portion on the substrate. The second portions are portions, whose orthographic projections on the substrate are located outside orthographic projections of the third electrodes on the substrate, of the second pixel circuits.

In some embodiments, a first region is within the orthographic projection of the second light-shielding portion on the substrate. The first region is a region between the plurality of second light-emitting devices in the main display region.

In some embodiments, the display panel further includes an electrode layer disposed between first electrodes of the at least some of the plurality of first sub-pixels and the plurality of first light-shielding portions. A portion, located in the functional device configuration region, of the electrode layer is provided with a plurality of second opening regions. At least a portion of orthographic projections of the plurality of second opening regions on the substrate are located in a region between orthographic projections of the plurality of first light-shielding portions on the substrate. A portion, located in the main display region, of the electrode layer has a continuous film layer structure.

In some embodiments, the first light-shielding portions are made of a same material and disposed in a same layer as the second light-shielding portion.

In some embodiments, the plurality of first sub-pixels further include a plurality of first filter portions. Each first filter portion corresponds to a single first opening region of a first light-shielding portion of the plurality of first light-shielding portions, and a border of an orthographic projection of the first filter portion on the substrate is located within an orthographic projection of the first light-shielding portion on the substrate. In a case where the display panel further includes a plurality of second sub-pixels and a second light-shielding portion, the plurality of second sub-pixels further include a plurality of second filter portions. Each second filter portion corresponds to a single third opening region of the second light-shielding portion, and a border of an orthographic projection of the second filter portion on the substrate is within an orthographic projection of the second light-shielding portion on the substrate.

In some embodiments, the display panel further includes an encapsulation layer. The encapsulation layer is disposed between the plurality of first light-shielding portions and the plurality of first light-emitting devices.

In some embodiments, the display panel further includes a plurality of signal lines. The plurality of signal lines are electrically connected to first pixel circuits of the at least some of the plurality of first sub-pixels. At least one signal line includes a signal trace and a transferring line. The signal trace is used for being connected with an external signal source. The transferring line is connected with a first pixel circuit of the first pixel circuits, and a portion, located in the functional device configuration region, of the signal trace is transparent.

In some embodiments, in a case where the display panel further comprises the plurality of signal lines, the plurality of signal lines include scanning signal lines, reset signal lines, enable signal lines and initialization signal lines.

The scanning signal lines include first scanning traces and first transferring lines. The first transferring lines extend in a first direction, and are electrically connected to the first pixel circuits. At least an end of each first scanning trace is located in the functional device configuration region so that the first scanning traces are electrically connected with the first transferring lines. Portions, located in the functional device configuration region, of the first scanning traces are transparent.

The reset signal lines include first reset traces and second transferring lines. The second transferring lines extend in the first direction, and are electrically connected to the first pixel circuits. At least an end of each first reset trace is located in the functional device configuration region so that the first reset traces are electrically connected with the second transferring lines. Portions, located in the functional device configuration region, of the first reset traces are transparent.

The enable signal lines include first enable traces and third transferring lines. The third transferring lines extend in the first direction, and are electrically connected to the first pixel circuits. At least an end of each first enable trace is located in the functional device configuration region so that the first enable traces are electrically connected with the third transferring lines. Portions, located in the functional device configuration region, of the first enable traces are transparent.

The initialization signal lines include first initialization traces and fourth transferring lines. The fourth transferring lines extend in the first direction, and are electrically connected to the first pixel circuits. At least an end of each first initialization trace is located in the functional device configuration region so that the first initialization traces are electrically connected with the fourth transferring lines. Portions, located in the functional device configuration region, of the first initialization traces are transparent.

In some embodiments, the display panel includes a semiconductor layer, a first gate conductive layer, a second gate conductive layer, a source-drain conductive layer and a transparent conductive layer that are sequentially disposed in a direction perpendicular to and away from the substrate. The first transferring lines, the second transferring lines and the third transferring lines are located in the first gate conductive layer, and the fourth transferring lines are located in the second gate conductive layer; and/or the portions, located in the functional device configuration region, of the first scanning traces, the first reset traces, the first enable traces and the first initialization traces are located in the transparent conductive layer.

In some embodiments, in a case where the display panel further comprises the plurality of signal lines, the plurality of signal lines further includes first voltage signal lines and data lines. The first voltage signal lines and the data lines extend in a second direction, and are both electrically connected to the first pixel circuits. At least portions, located in the functional device configuration region, of the first voltage signal lines and at least portions, located in the functional device configuration region, of the data lines are transparent.

In some embodiments, the first voltage signal lines include first voltage traces and fifth transferring lines. The fifth transferring lines are disposed on a side of the first pixel circuits away from the substrate, and electrically connected to the first voltage traces.

In some embodiments, the display panel includes a semiconductor layer, a first gate conductive layer, a second gate conductive layer, a source-drain conductive layer, a transparent conductive layer and a second source-drain conductive layer that are sequentially disposed in a direction perpendicular to and away from the substrate. Portions, located in the functional device configuration region, of the first voltage traces and the portions, located in the functional device configuration region, the data lines are located in the transparent conductive layer. The fifth transferring lines are located in the second source-drain conductive layer.

In another aspect, a display apparatus is provided. The display apparatus includes a housing and the display panel as described in any one of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person having ordinary skill in the art can obtain other drawings according to these accompanying drawings. In addition, the accompanying drawings in the following description may be regarded as schematic diagrams, but are not limitations on an actual size of a product, an actual process of a method and an actual timing of a signal involved in the embodiments of the present disclosure.

FIG. 1 is a structural diagram of a display apparatus, in accordance with some embodiments;

FIG. 2 is an exploded view of a display apparatus, in accordance with some embodiments;

FIG. 3A is a section of a functional device configuration region of a display panel, in accordance with some embodiments;

FIG. 3B is a section of a main display region of a display panel, in accordance with some embodiments;

FIG. 4 is an equivalent circuit diagram of a pixel driving circuit, in accordance with some embodiments;

FIG. 5 is a timing diagram of a pixel driving circuit, in accordance with some embodiments;

FIG. 6A is a top view, showing an arrangement of pixel circuits, of a functional device configuration region of a display panel, in accordance with some embodiments;

FIG. 6B is a top view, showing an arrangement of light-emitting devices, of the functional device configuration region of the display panel, in accordance with some embodiments;

FIG. 6C is a top view of the functional device configuration region, provided with first light-shielding portions, of the display panel, in accordance with some embodiments;

FIG. 6D is a top view of a function device configuration region, provided with first light-shielding portions, of another display panel, in accordance with some embodiments;

FIG. 6E is a top view of a function device configuration region of still another display panel, in accordance with some embodiments;

FIG. 7 is a structural diagram of a first light-shielding portion of a display panel, in accordance with some embodiments;

FIG. 8 is an enlarged view of a pixel unit of a functional device configuration region of a display panel, in accordance with some embodiments;

FIG. 9A is a top view, showing an arrangement of pixel circuits, of a main display region of a display panel, in accordance with some embodiments;

FIG. 9B is a top view, showing an arrangement of light-emitting devices, of the main display region of the display panel, in accordance with some embodiments;

FIG. 9C is a top view of the main display region, provided with a second light-shielding portion, of the display panel, in accordance with some embodiments;

FIG. 9D is a top view of a main display region, provided with a second light-shielding portion, of another display panel, in accordance with some embodiments;

FIG. 10A is a structural diagram of a second light-emitting region of a display panel, in accordance with some embodiments;

FIG. 10B is an enlarged view of a red sub-pixel of a main display region of a display panel, in accordance with some embodiments;

FIG. 11 is a top view of a semiconductor layer of a functional device configuration region of a display panel, in accordance with some embodiments;

FIG. 12 is a top view of a structure obtained by adding a first gate conductive layer onto the semiconductor layer of the functional device configuration region shown in FIG. 11;

FIG. 13 is a top view of a structure obtained by adding a second gate conductive layer onto the first gate conductive layer of the functional device configuration region shown in FIG. 12;

FIG. 14 is a top view of a structure obtained by adding a first source-drain conductive layer onto the second gate conductive layer of the functional device configuration region shown in FIG. 13;

FIG. 15 is a top view of a structure obtained by adding a transparent conductive layer onto the first source-drain conductive layer of the functional device configuration region shown in FIG. 14;

FIG. 16 is a top view of a structure obtained by adding a second source-drain conductive layer onto the transparent conductive layer of the functional device configuration region shown in FIG. 15;

FIG. 17 is a top view of a structure obtained by adding a first electrode onto the second source-drain conductive layer of the functional device configuration region shown in FIG. 16;

FIG. 18 is a top view of a semiconductor layer of a main display region of a display panel, in accordance with some embodiments;

FIG. 19 is a top view of a structure obtained by adding a first gate conductive layer onto the semiconductor layer of the main display region shown in FIG. 18;

FIG. 20 is a top view of a structure obtained by adding a second gate conductive layer onto the first gate conductive layer of the main display region shown in FIG. 19;

FIG. 21 is a top view of a structure obtained by adding a first source-drain conductive layer onto the second gate conductive layer of the main display region shown in FIG. 20;

FIG. 22 is a top view of a structure obtained by adding a transparent conductive layer onto the first source-drain conductive layer of the main display region shown in FIG. 21;

FIG. 23 is a top view of a structure obtained by adding a second source-drain conductive layer onto the transparent conductive layer of the main display region shown in FIG. 22; and

FIG. 24 is a top view of a structure obtained by adding first electrodes onto the second source-drain conductive layer of the main display region shown in FIG. 23.

### DETAILED DESCRIPTION

Technical solutions in some embodiments of the present disclosure will be described clearly and completely below with reference to the accompanying drawings. However, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representation of the above terms does not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/the plurality of” means two or more unless otherwise specified.

In embodiments may be described using the terms “coupled” and “connected” and their derivatives. For example, the term “connected” may be used in the description of some embodiments to indicate that two or more components are in direct physical or electrical contact with each other. The embodiments disclosed herein are not necessarily limited to the content herein. For another example, the term “coupled” may be used in the description of some embodiments to indicate that two or more components are in direct physical or electrical contact. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

As used herein, the terms such as “parallel”, “perpendicular” or “equal” include a stated case and a case similar to the stated case. The similar case is within an acceptable range of deviation, and the acceptable range of deviation is determined by a person of ordinary skill in the art in view of measurement in question and errors associated with measurement of a particular quantity (i.e., limitations of a measurement system). For example, the term “parallel” includes absolute parallelism and approximate parallelism, and an acceptable range of deviation of the approximate parallelism may be a deviation within 5°. For example, the term “perpendicular” includes absolute perpendicularity and approximate perpendicularity, and an acceptable range of deviation of the approximate perpendicularity may be a deviation within 5°. The term “equal” includes absolute equality and approximate equality, and an acceptable range of deviation of the approximate equality may refer to that, a difference between two equals is less than or equal to 5% of either of the two equals.

It will be understood that, in a case where a layer or a component is described as being on another layer or a substrate, it may be that the layer or the component is directly on the another layer or the substrate, or that intermediate layer(s) exist between the layer the component and the another layer or the substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the region in a device, and are not intended to limit the scope of the exemplary embodiments.

Transistors adopted in pixel driving circuits (pixel circuits) provided in embodiments of the present disclosure may be thin film transistors (TFTs), field-effect transistors (FETs, e.g., metal-oxide-semiconductor FETs (MOSFETs)) or other switching devices with same characteristics. Embodiments of the present disclosure are all described by taking an example where the transistors are thin film transistors.

In addition, the pixel driving circuits (the pixel circuits) provided in the embodiments of the present disclosure are all described by taking an example where the transistors are P-type transistors. It will be noted that, embodiments of the present disclosure include but are not limited to such an example. For example, one or more transistors in a driving circuit provided in the embodiments of the present disclosure may also adopt N-type transistors, as long as coupling of electrodes of the selected type transistors is performed with reference to electrodes of corresponding transistors in the embodiments of the present disclosure, and corresponding high voltages or corresponding low voltages are provided through corresponding voltage terminals.

Herein, control electrodes of the thin film transistors adopted in the pixel driving circuits are gates of the transistors, first electrodes of the thin film transistors are one of sources and drains of the thin film transistors, and second electrodes of the thin film transistors are the other one of the sources and the drains of the thin film transistors. Since a source and a drain of a thin film transistor may be symmetrical in structure, the source and the drain of the thin film transistor may be structurally indistinguishable. That is to say, there may be no difference in structure between the first electrodes and the second electrodes of the thin film transistors in the embodiments of the present disclosure. For example, in a case where the thin film transistors are P-type transistors, the first electrodes of the thin film transistors may be sources, and the second electrodes of the thin film transistors may be drains. For example, in a case where the thin film transistors are N-type transistors, the first electrodes of the thin film transistors may be drains, and the second electrodes of the thin film transistors may be sources.

For the pixel driving circuits (the pixel circuits) provided in the embodiments of the present disclosure, capacitors may be capacitors formed by an individual process. For example, the capacitors are obtained by forming special capacitor electrodes, and each capacitor electrode of the capacitors may be obtained by means of a metal layer, a semiconductor layer (e.g., doped polysilicon), etc. The capacitors may also be parasitic capacitors between the transistors, between the transistors and some other devices or lines, or between lines of the circuits themselves.

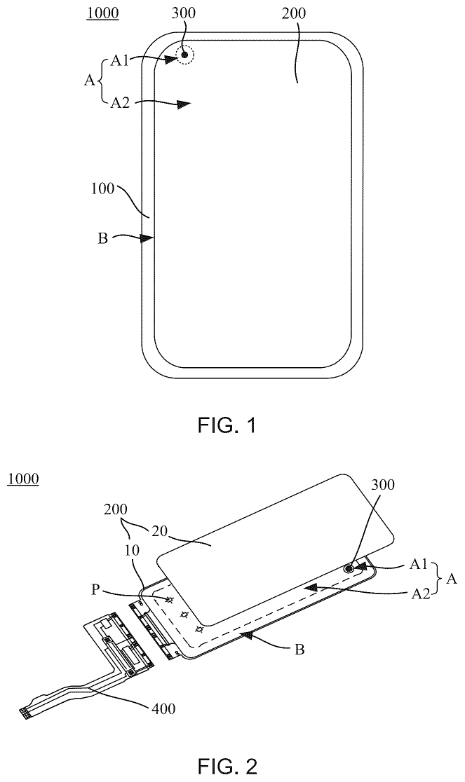

With reference to FIG. 1, embodiments of the present disclosure provide a display apparatus 1000. The display apparatus 1000 may be any apparatus that displays images whether in motion (e.g., videos) or stationary (e.g., still images) and whether text or images. For example, the display apparatus 1000 may be any product or component having a display function, such as a television, a notebook computer, a tablet computer, a mobile phone, a personal digital assistant (PDA), a navigator, a wearable apparatus or a virtual reality (VR) apparatus.

Here, the display apparatus 1000 is n electroluminescent display apparatus or a photoluminescent display apparatus. In a case where the display apparatus is an electroluminescent display apparatus, the electroluminescent display apparatus may be an organic electroluminescent display apparatus (e.g., an organic light-emitting diode (OLED) display apparatus) or a quantum dot electroluminescent display apparatus (e.g., a quantum dot light-emitting diode (QLED) display apparatus). In a case where the display apparatus is a photoluminescent display apparatus, the photoluminescent display apparatus may be a quantum dot photoluminescent display apparatus.

In some examples, with reference to FIGS. 1 and 2, the display apparatus 1000 includes a housing 100 and a display panel 200, a functional device 300, a circuit board 400 and other electronic accessories that are disposed in the housing 100.

The circuit board 400 may be bonded to the display panel 200 at an end of the display panel 200, and disposed on a back side of the display panel 200 through bending, so as to realize a full-screen design. The functional device 300 may be integrated with the display panel 200 on the back side of the display panel 200 so as to realize the full screen design.

It will be noted that, the functional device 300 may be a camera, an infrared sensor, a proximity sensor, an eyeball tracking module, a face recognition module, etc. For example, with reference to FIGS. 1 and 2, the functional device 300 is a camera.

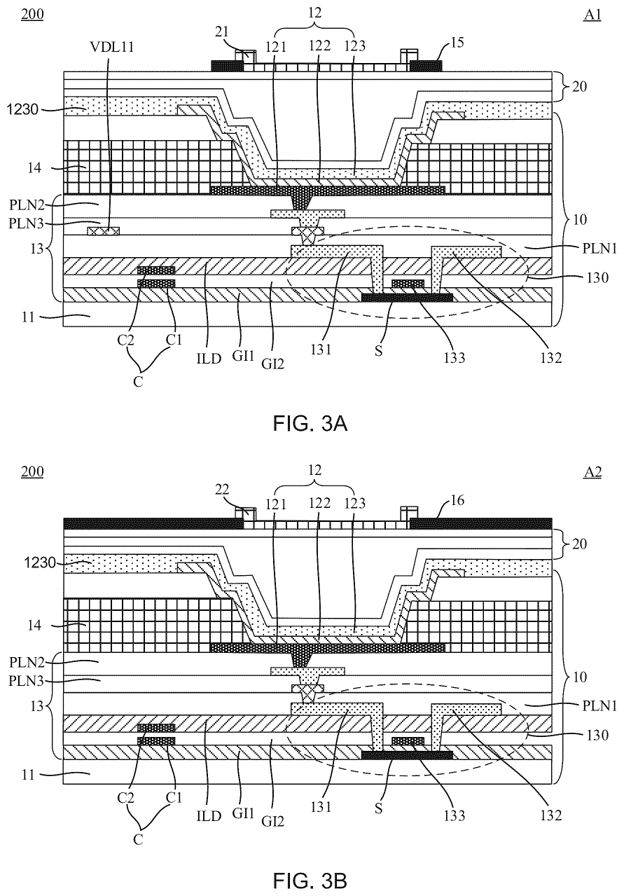

In some embodiments, as shown in FIGS. 2, 3A and 3B, the display panel 200 includes a display substrate 10 and an encapsulation layer 20 for encapsulating the display substrate 10.

The display substrate 10 includes a substrate 11, and has a light-exit side and a non-light-exit side that are disposed opposite to each other. The encapsulation layer 20 is disposed on the light-exit side of the display substrate 10. Here, the encapsulation layer 20 may be an encapsulation film or an encapsulation substrate.

With reference to FIG. 2, the display panel 200 has a display region A and a peripheral region B disposed on at least one side of the display region A. FIG. 2 illustrates an example where the peripheral region B is disposed around the display region A.

Here, the display region is a region for displaying images, and is configured to hold a plurality of pixel units P. The peripheral region B is a region where no image is displayed, and is configured to hold driving circuits, such as a gate driving circuit and a source driving circuit, for performing display.

It will be noted that, in a case where the functional device 300 is integrated with the display panel 20 on the back side of the display panel 200, the display region A has a functional device configuration region A1 and a main display region A2 at least partially surrounding the functional device configuration region A1. The functional device 300 is located in the functional device configuration region A1. FIGS. 1 and 2 illustrate examples where the main display region A2 surrounding the functional device configuration region A1.

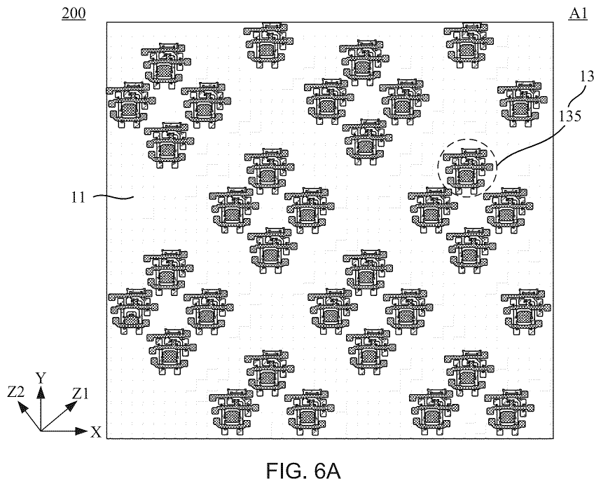

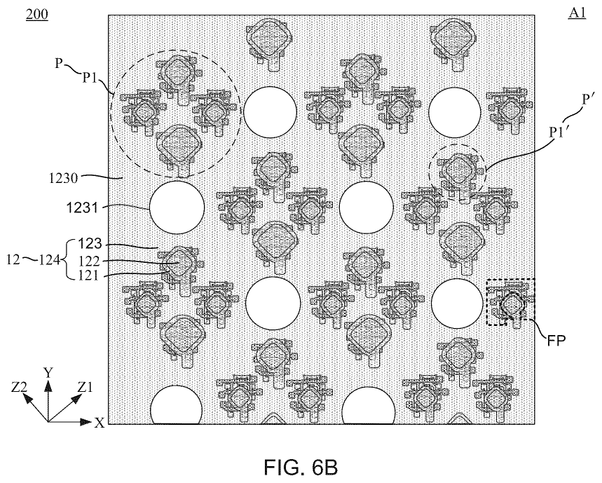

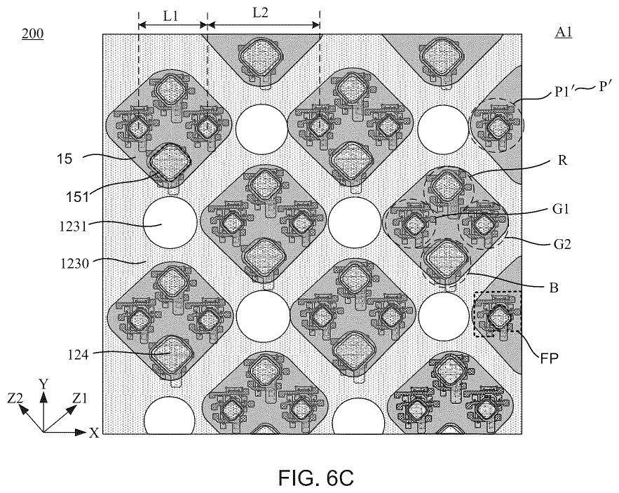

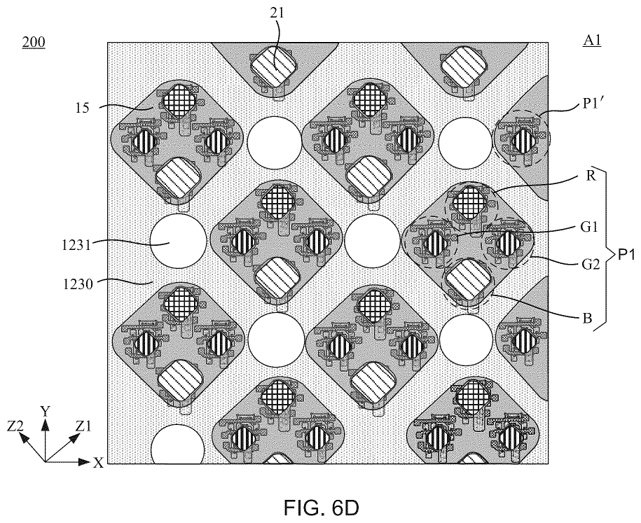

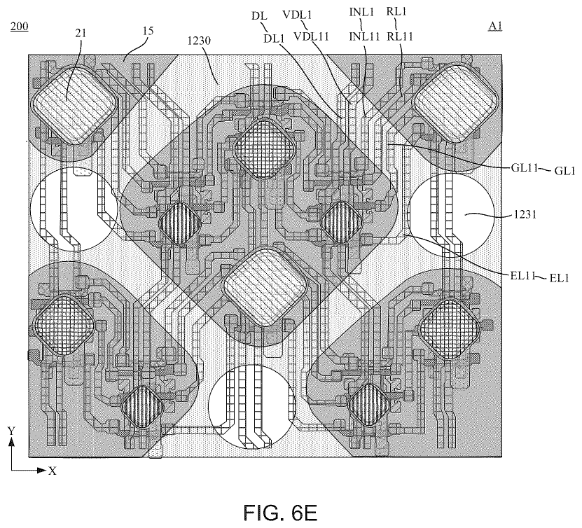

For example, with reference to FIGS. 2 and 6B, the display region A of the display panel 200 is provided with a plurality of pixel units P, and each pixel unit P may include sub-pixels P′ emitting light of a plurality of colors. For example, the sub-pixels P′ emitting light of the plurality of colors include red sub-pixels, green sub-pixels and blue sub-pixels.

With reference to FIGS. 3A and 3B, each sub-pixel P′ includes a light-emitting device 12 and a pixel driving circuit 13 that are disposed on the substrate 11. The pixel driving circuit 13 includes a plurality of transistors 130. A transistor 130 includes a channel region S, a source 131, a drain 132 and a gate 133. The source 131 and the drain 132 are both in contact with the channel region S. In a direction perpendicular to and away from the substrate 11, the light-emitting device 12 includes a first electrode 121, a light-emitting functional layer 122 and a second electrode 123.

Here, with reference to FIGS. 6A and 6B, orthographic projections of portions of pixel driving circuits 13 on the substrate 11 are located outside orthographic projections of first electrodes 121 on the substrate 11. That is, portions of edges of the pixel driving circuits 13 are not shielded by the first electrodes 121.

It will be noted that, for convenience of description, a pixel circuit 13 mentioned below is referred to as the pixel driving circuit 13.

Here, the first electrode 121 is an anode of the light-emitting device 12, and the second electrode 123 is a cathode of the light-emitting device 12. Alternatively, the first electrode 121 may be a cathode of the light-emitting device 12, and the second electrode 123 may be an anode of the light-emitting device 12.

For example, with reference to FIGS. 3A and 3B, the first electrode 121 is an anode of the light-emitting device 12, and the second electrode 123 is a cathode of the light-emitting device 12. The first electrode 121 is electrically connected to a source 131 or a drain 132 of a transistor 130 of the pixel circuit 13. FIGS. 3A and 3B illustrate examples where the first electrode 121 is electrically connected to the source 131 of the transistor 130 of the pixel circuit 13.

In some embodiments, the light-emitting functional layer 122 only includes a light-emitting layer. In some other embodiments, in addition to the light-emitting layer, the light-emitting functional layer 122 further includes at least one of an electron transport layer (ETL), an electron injection layer (EIL), a hole transport layer (HTL) and a hole injection layer (HIL).

In addition, a structure of the pixel circuit 13 may vary, which may be determined depending on actual needs. For example, the structure of the pixel circuit 13 may be a structure of “2T1C”, “3T1C”, “6T1C”, “7T1C”, “6T2C” or “7T2C”. Here, “T” represents “transistor”, a number in front of “T” represents the number of transistors, “C” represents “storage capacitor”, and a number in front of “C” represents the number of storage capacitors.

During the use of the display panel 200, stabilities of the transistors of the pixel circuit 13 and the light-emitting device 12 may decrease (e.g., a threshold voltage of a driving transistor drifts), which affects display effects of the display panel 200. Therefore, compensation for the pixel circuit 13 is required.

A manner in which the pixel circuit 13 is compensated may vary, which may be determined depending on actual needs. For example, it may be possible to provide a pixel compensation circuit into the pixel circuit 13, so that the pixel compensation circuit may be used to perform internal compensation for the pixel circuit 13. For another example, it may be possible to sense the driving transistor or the light-emitting device 22 by means of a transistor of the pixel circuit 13, and sensed data may be transmitted to an external sensing circuit, so that a required driving voltage value for compensation is calculated by using the external sensing circuit, and then feedback is performed, thereby realizing external compensation for the pixel circuit 13.

The structure and an operating process of the pixel circuit 13 are schematically illustrated by taking an example where an external compensation manner is adopted and the pixel drive circuit 13 adopts a 3T1C structure in the present disclosure.

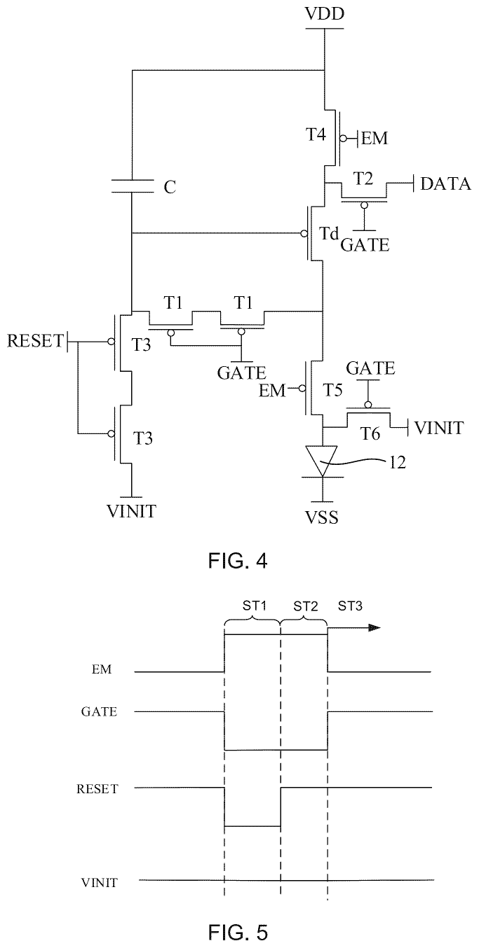

For example, as shown in FIG. 4, the pixel circuit 13 includes a first transistor T1, a second transistor T2, a third transistor T3, a fourth transistor T4, a fifth transistor T5, a sixth transistor T6, a seventh transistor T7, a driving transistor Td and a storage capacitor C.

A control electrode of the first transistor T1 is electrically connected to a scanning signal terminal GATE, a first electrode of the first transistor T1 is electrically connected to a second electrode of the driving transistor Td, and a second electrode of the first transistor T1 is electrically connected to a control electrode of the driving transistor Td.

A control electrode of the second transistor T2 is electrically connected to the scanning signal terminal GATE, a first electrode of the second transistor T2 is electrically connected to a data signal terminal DATA, and a second electrode of the second transistor T2 is coupled to a first electrode of the driving transistor Td.

A control electrode of the third transistor T3 is electrically connected to a reset signal terminal RESET, a first electrode of the third transistor T3 is electrically connected to an initialization signal terminal VINIT, and a second electrode of the third transistor T3 is electrically connected to the control electrode of the driving transistor Td.

A control electrode of the fourth transistor T4 is electrically connected to an enable signal terminal EM, a first electrode of the fourth transistor T4 is electrically connected to a first voltage signal terminal VDD, and a second electrode of the fourth transistor T4 is electrically connected to the first electrode of the driving transistor Td.

A control electrode of the fifth transistor T5 is electrically connected to the enable signal terminal EM, a first electrode of the fifth transistor T5 is electrically connected to the second electrode of the driving transistor Td, and a second electrode of the fifth transistor T5 is electrically connected to the first electrode 121 (in conjunction with FIG. 3A) of the light-emitting device 12.

A control electrode of the sixth transistor T6 is electrically connected to the scanning signal terminal GATE, a first electrode of the sixth transistor T6 is electrically connected to the initialization signal terminal VINIT, and a second electrode of the sixth transistor T6 is electrically connected to the first electrode 121 (in conjunction with FIG. 3A) of the light-emitting device 12.

A first electrode plate C1 of the first storage capacitor C is electrically connected to the control electrode of the driving transistor Td, and a second electrode plate C2 of the storage capacitor C is electrically connected to the first voltage signal terminal VDD.

Based on the above structure of the pixel circuit 13 in FIG. 4, as shown in FIGS. 5, in a single frame of display, an operation process of the sub-pixel may have, for example, a reset stage ST1, a data writing stage ST2 and a light-emitting stage ST3.

In the reset stage ST1, the sixth transistor T6 is turned on under control of a scanning signal Gate from the scanning signal terminal GATE, so that a voltage of the first electrode of the light-emitting device 12 is reset to an initialization voltage signal Vinit; and the third transistor T3 is turned on under control of a reset signal Reset from the reset signal terminal RESET, so that a voltage of the control electrode of the driving transistor Td and a voltage of the first electrode plate C1 of the storage capacitor C are reset to the initialization voltage signal Vinit.

In the data writing stage ST2, the first transistor T1 and the second transistor T2 are turned on under the control of the scanning signal Gate from the scanning signal terminal GATE, and the driving transistor Td is turned on under control of the initialization voltage signal stored in the storage capacitor C, so that a data signal Data from the data signal terminal DATA is written into the storage capacitor C.

In the light-emitting stage ST3, the fourth transistor T4 and the fifth transistor T5 are turned on under control of an enable signal Em of the enable signal terminal EM, so that a driving current signal is output to the light-emitting device 12 to drive the light-emitting device 12 to emit light.

In some embodiments, as shown in FIGS. 3A and 3B, the display substrate 10 further includes a pixel defining layer 14. The pixel defining layer 14 is disposed on a side of the first electrode 121 away from the substrate 11. The pixel defining layer 14 includes a plurality of opening regions. A single light-emitting device 12 is disposed in a respective opening region. That is, a light-emitting functional layer 122 of the light-emitting device 12 is in contact with a respective first electrode 121.

It will be noted that, in order to reduce process difficulty, an area of the first electrode 121 is greater than an area of the respective opening region of the pixel defining layer 14, which ensures that the entire opening region of the pixel defining layer 14 is an light-emitting region of the light-emitting device 12. That is, a portion, where the first electrode 121, the second electrode 123 and the light-emitting functional layer 122 overlap with each other, of the light-emitting device 12 forms the light-emitting region of the light-emitting device 12. That is, a portion, where the first electrode 121, the second electrode 123 and the light-emitting functional layer 122 opposite to a region where the opening region of the pixel defining layer 14 is located, of the light-emitting device 12 forms the light-emitting region of the light-emitting device 12.

It will be understood that, in the case where the functional device 300 is integrated with the display panel 200 on the back side of the display panel 200, a poor light transmittance of the display panel 200 is adverse to light sensitivity of the functional device 300 on the back side of the display panel 200, while a high reflectivity of the display panel 200 is adverse to the display effects of the display panel 200.

In view of this, in some related art, a polarizer is provided on a light-exit side of a display panel to reduce a reflection intensity of external ambient light by the display panel. However, 50% to 60% of light emitted by the display panel is lost after the light passes through the polarizer. That is, the polarizer greatly reduces a transmittance of a display apparatus. Consequently, a power consumption of the display apparatus is increased, and light sensitivity of a camera on a back side of the display panel is affected. In addition, since portions of edges of pixel circuits are not shielded by first electrodes, the external ambient light is reflected by the portions of the edges of the pixel circuits to generate a severe diffraction problem, which causes a decrease in light sensitivity of a functional device.

In some other related art, a color filter layer is provided on a light-exit side of a display panel instead of a polarizer. However, compared with the relate art where a polarizer is provided on the light-exit side of the display panel, a reflection intensity of the external ambient light by the display panel is still large. Especially, for a region where a camera is located, in order to ensure light sensitivity of the functional device, a light-shielding layer cannot completely cover a region, between pixels, of the region where the camera is located. Thus, reflection intensity in the functional device configuration region is too large, which affects the display effects. In addition, since portions of edges of pixel circuits are not shielded by first electrodes, the external ambient light is reflected by the portions of the edges of the pixel circuits to generate a severe diffraction problem, which causes a decrease in light sensitivity of the functional device.

In view of this, some embodiments of the present disclosure provide a display panel 200. With reference to FIGS. 6C and 6D, the display panel 200 further includes a plurality of first light-shielding portions 15.

It will be noted that, in order to distinguish pixel units P, sub-pixels P′, light-emitting devices 12 and pixel circuits 13 in the functional device configuration region A1 from pixel units P, sub-pixels P′, light-emitting devices 12 and pixel circuits 13 in the main display region A2, the pixel units P, the sub-pixels P′, the light-emitting devices 12 and the pixel circuits 13 located in the functional device configuration region A1 are respectively referred to as first pixel units P1, first sub-pixels P1′, first light-emitting devices 124 and first pixel circuits 135 herein, and the pixel units P, the sub-pixels P′, the light-emitting devices 12 and the pixel circuits 13 located in the main display region A2 are respectively referred to as second pixel units P2, second sub-pixels P2′, second light-emitting devices 125 and second pixel circuits 136 herein.

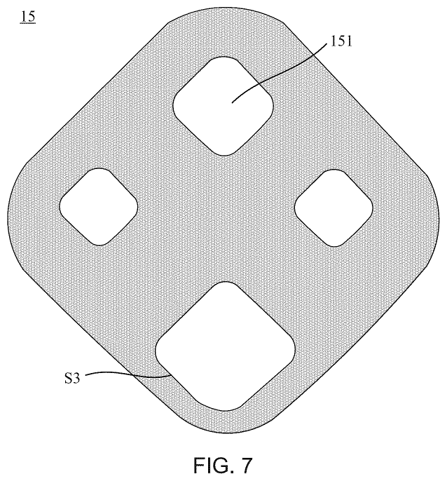

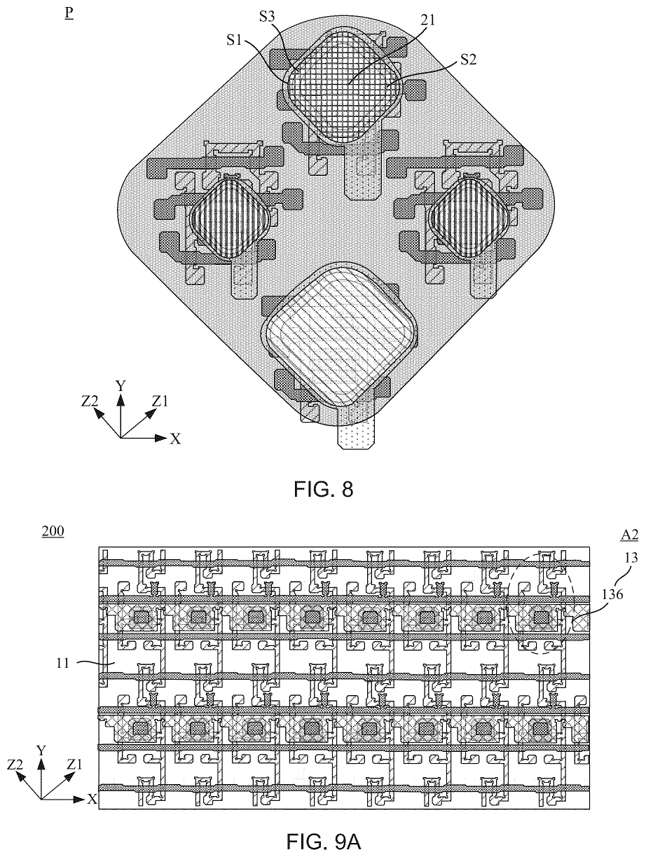

FIGS. 6A to 6D are top views of the functional device configuration region of the display panel in accordance with some embodiments. FIG. 7 is a structural diagram of a first light-shielding portion of the display panel in accordance with some embodiments. FIG. 8 is an enlarged view of a single pixel unit in the functional device configuration region of the display panel in accordance with some embodiments.

In conjunction with FIGS. 6A to 6D, the plurality of first light-shielding portions 15 are arranged at intervals on a side of a plurality of first light-emitting devices 124 away from the substrate 11, and located in the functional device configuration region A1. In conjunction with FIGS. 6B, 6C and 7, each first light-shielding portion 15 is provided with a plurality of first opening regions 151, each first opening region 151 corresponds to a single first light-emitting device 124, and a light-emitting region of the first light-emitting device 124 is located in the first opening region 151.

In conjunction with FIGS. 6A to 6D, orthographic projections of first portions FP of the first pixel circuits 135 on the substrate 11 are located within orthographic projections of the first light-shielding portions 15 on the substrate 11. A first portion FP is a portion, whose orthographic projection on the substrate 11 is located outside an orthographic projection of a first electrode 121 on the substrate 11, of a first pixel circuit 135.

In this case, in the functional device configuration region A1, the orthographic projections of the first portions FP of the first pixel circuits 135 on the substrate 11 are located within the orthographic projections of the first light-shielding portions 15 on the substrate 11. That is to say, the orthographic projections of the first pixel circuits 135 on the substrate 11 are located in a range defined by the orthographic projections of the first electrodes 121 and the orthographic projections of the first light-shielding portions 15 on the substrate 11. In this way, the external environment light may be prevented from directly irradiating on the first pixel circuits 135, which reduces reflection intensity of the external environment light in the functional device configuration region A1 of the display panel 200 and prevents the diffraction problem caused by the external environment light directly irradiating on edges of the first pixel circuits 135, thereby improving the light sensitivity of the functional device 300. In addition, channel regions S of transistors 130 (e.g., first transistors T1) of the first pixel circuits 135 may be shielded by the first electrodes 121 and the first light-shielding portions 15, so that a drift risk of threshold voltages of the transistors 130 is reduced, which improves accuracy of driving currents and the display effects in the functional device configuration region A1 of the display panel 200.

In some embodiments, as shown in FIGS. 6C and 7, each first light-shielding portion 15 corresponds to a single first pixel unit P1. That is, the plurality of first opening regions 151 of each first light-shielding portion 15 correspond to multiple first sub-pixels P1′ of a same first pixel unit P1 in a one-to-one manner. In this way, shielding areas of the first light-shielding portions 15 for respective first pixel units P1 are same as each other, which avoids a problem of luminance non-uniformity or color cast caused by different light-transmitting areas for the plurality of first pixel units P1. Therefore, the display effects of the display panel 200 in the functional device configuration region A1 are improved.

It will be understood that, in order to reduce the areas of the first light-shielding portions 15 and reduce an influence of the first light-shielding portions 15 on the transmittance of the display panel 200 in the functional device configuration region A1, as shown in FIG. 6C, for multiple first sub-pixels P1′ located in an outer border of a same first light-shielding portion 15, a distance between centers of two first sub-pixels P1′ that are adjacent to each other in a setting direction is a first distance L1. In the setting direction, a distance between centers of two adjacent first sub-pixels P1′, which are respectively located within outer borders of two adjacent first light-shielding portions 15, is a second distance L2. The first distance L1 is less than the second distance L2. FIG. 6C illustrates an example where the setting direction is a first direction X.

It will be noted that, in order to increase the transmittance of the display panel 200 in the functional device configuration region A1, the first pixel circuits 135 in the functional device configuration region A1 are designed to be compact. As shown in FIGS. 6A and 6B, in the functional device configuration region A1, an arrangement of the first pixel circuits 135 is similar to an arrangement of the first light-emitting devices 124. In this case, a geometric center of a first pixel circuit 135 substantially coincides with a geometric center of a respective first light-emitting device 124. Based on this, a center of a first sub-pixel P1′ may refer to a center of a light-emitting region of a first light-emitting device 124 of the first sub-pixel P1′.

The setting direction may be an arrangement direction of any adjacent two first sub-pixels P1′.

In this case, since distances between the multiple first sub-pixels P1′ which the first light-shielding portion 15 needs to shield are shortened, an area of the first light-shielding portion 15 may be correspondingly decreased. In this way, the transmittance of the display panel 200 in the functional device configuration region A1 is improved. In addition, since distances between adjacent first light-shielding portions 15 are lengthened, difficulty of a process for forming the first light-shielding portions 15 is reduced.

In some embodiments, with reference to FIGS. 6B, 6C and 6D, the plurality of first sub-pixels P1′ include a plurality of red sub-pixels R, a plurality of first green sub-pixels G1, a plurality of second green sub-pixels G2 and a plurality of blue sub-pixels B. The plurality of red sub-pixels R and the plurality of first green sub-pixels G1 are alternately arranged in a first oblique direction Z1, and the plurality of red sub-pixels R and the plurality of second green sub-pixels G2 are alternately arranged in a second oblique direction Z2. The blue sub-pixels B and the second green sub-pixels G2 are alternately arranged in the first oblique direction Z1, and the blue sub-pixels B and the plurality of first green sub-pixels G1 are alternately arranged in the second oblique direction Z2. The first green sub-pixels G1 and the second green sub-pixels G2 are alternately arranged in the first direction X. The red sub-pixels R and the blue sub-pixels B are alternately arranged in the second direction Y.

The first direction X is substantially perpendicular to the second direction Y. The first oblique direction Z1 intersects the second oblique direction Z2. The first oblique direction Z1 and the second oblique direction Z2 both intersect the first direction X. The first oblique direction Z1 and the second oblique direction Z2 both intersect the second direction Y.

It will be noted that, an included angle between the first oblique direction Z1 and the first direction X may be approximately in a range of 40 degrees to 50 degrees, inclusive. An included angle between the first oblique direction Z1 and the second direction Y may be approximately in a range of 40 degrees to 50 degrees, inclusive. An included angle between the second oblique direction Z2 and the first direction X may be approximately in a range of 130 degrees to 140 degrees, inclusive. An included angle between the second oblique direction Z1 and the second direction Y may be approximately in a range of 40 degrees to 50 degrees, inclusive.

In this case, the setting direction may be any one of the first direction X, the second direction Y, the first oblique direction Z1 and the second oblique direction Z2. That is to say, in a case where each first pixel unit P1 corresponds to a first light-shielding portion 15, distances between multiple first sub-pixels P1′ located in a same first pixel unit P1 are shortened, so that the multiple first sub-pixels P1′ are close to each other.

On this basis, with reference to FIGS. 6B and 6D, each first pixel unit P1 may include one red sub-pixel R, one first green sub-pixel G1, one second green sub-pixel G2 and one blue sub-pixel B that are adjacent to each other. That is, four first sub-pixels P1′ constitute a single minimum repeating unit. In the same first pixel unit P1, the red sub-pixel R and the blue sub-pixel B are arranged in the second direction Y, and the first green sub-pixel G1 and the second green sub-pixel G2 are arranged in the first direction X.

In this case, an outer border of the first light-shielding portion 15 may be substantially in a shape of a rhombus, and two diagonal lines of the rhombus are substantially parallel to the first direction X and the second direction Y, respectively.

It will be noted that, “be substantially in a shape of a rhombus” herein means that the shape is a rhombic overall, but is not limited to a standard rhombus. That is, the “rhombus” herein includes not only a standard rhombus but also a shape similar to a rhombus in consideration of process conditions. For example, a corner of the rhombus is curved. That is, the coiner is smooth.

In some embodiments, with reference to FIG. 6B, the first pixel units P1 are arranged in a plurality of rows and a plurality of columns. Each row includes multiple first pixel units P1 arranged in the first direction X, and each column includes multiple first pixel units P1 arranged in the second direction Y. On this basis, with reference to FIG. 6C, the plurality of first light-shielding portions 15 are arranged in a plurality of rows and a plurality of columns. Each row includes multiple first light-shielding portions 15 arranged in the first direction X, and each column includes multiple first light-shielding portions 15 arranged in the second direction Y.

Here, with reference to FIG. 6B, multiple first pixel units P1 in a row may be staggered with multiple first pixel units P1 in another row adjacent thereto, and multiple first pixel units P1 in a column may be staggered with multiple first pixel units P1 in another column adjacent thereto. In this way, an arrangement of the first pixel units P1 is compact, which improves the display effects. On this basis, with reference to FIG. 6C, multiple first light-shielding portions 15 in a row may be staggered with multiple first light-shielding portions 15 in another row adjacent thereto, and multiple first light-shielding portions 15 in a column may be staggered with multiple first light-shielding portions 15 in another column adjacent thereto.

In some embodiments, as shown in FIGS. 3A, 3B and 6B, the display panel 200 further includes an electrode layer 1230. The electrode layer 123 includes second electrodes 123 of the light-emitting devices 12, and is disposed between the first electrodes 121 and the first light-shielding portions 15.

A portion, located in the functional device configuration region A1, of the electrode layer 1230 is provided with a plurality of second opening regions 1231. Orthographic projections of the second opening regions 1231 on the substrate 11 are located in a region between the orthographic projections of the plurality of first light-shielding portions 15 on the substrate 11 (in conjunction with FIG. 6A). In this way, it may be possible to reduce an area of a portion, located between the first light-shielding portions 15, of the electrode layer 1230, so that reflection of ambient light by the electrode layer 1230 is reduced, which further reduces the reflection intensity of the ambient light in the functional device configuration region A1 of the display panel 200.

It will be understood that, a second opening region 1231 may be provided between any adjacent two first light-shielding portions 15. For example, the plurality of first light-shielding portions 15 are arranged in the plurality of rows and the plurality of columns, each row including multiple first light-shielding portions 15 arranged in the first direction X, and each column including multiple first light-shielding portions 15 arranged in the second direction Y. In this case, two first light-shielding portions 15 that are adjacent to each other in the first direction X may be provided therebetween with a second opening region 1231, or two first light-shielding portions 15 that are adjacent to each other in the second direction Y may be provided therebetween with a second opening region 1231.

As shown in FIG. 6C, multiple first light-shielding portions 15 in a row may be staggered with multiple first light-shielding portions 15 in another row adjacent thereto, multiple first light-shielding portions 15 in a column may be staggered with multiple first light-shielding portions 15 in another column adjacent thereto, and outer borders of the first light-shielding portions 15 are substantially in a shape of a rhombus. In this case, the second opening regions 1231 are located between first light-shielding portions 15 that are adjacent to each other in the first direction X and between first light-shielding portions 15 that are adjacent to each other in the second direction Y. In this case, an area of a region between adjacent first light-shielding portions 15 in the first direction X and an area of a region between adjacent first light-shielding portions 15 in the second direction Y are large, which reduces difficulty of a process of patterning the electrode layer 1230, i.e., is conductive to forming the second opening regions 1231 of the electrode layer 1230.

Here, the second opening region 1231 is in a shape of a substantial circle or a substantial ellipse. It will be understood that, by using a shape of a circle or en ellipse, areas of the second opening regions 1231 may be set relatively large. This means that an area, between the first light-shielding portions 15, of a portion of the electrode layer 1230 may be reduced. Therefore, the reflection intensity of the external ambient light in the functional device configuration region A1 of the display panel 200 is reduced.

It will be noted that, the description “a shape of a substantial circle or a substantial ellipse” means that the shape is a circle or an ellipse overall, but is not limited to a standard circle or a standard elliptical. That is, the circle or the ellipse herein includes not only a standard circle or a standard elliptical but also a shape similar to a circle or an ellipse in consideration of process conditions. For example, a portion of a border of the shape similar to a circle or an ellipse is a straight line segment.

It will be understood that, with reference to FIG. 6B, the first light-emitting devices 124 of the first sub-pixels P1′ may be configured to emit white light or colored light.

For example, with reference to FIG. 6C, the first light-emitting devices 124 of the first sub-pixels P1′ are configured to emit colored light, and the colored light directly exits to an outside of the display panel 200.

For example, as shown in FIG. 6C, the plurality of first sub-pixels P1′ includes the red sub-pixels R, the first green sub-pixels G1, the second green sub-pixels G2 and the blue sub-pixels B. First light-emitting devices 124 of the red sub-pixels R is configured to emit red light, first light-emitting devices 124 of the first green sub-pixels G1 and first light-emitting devices 124 of the second green sub-pixel G2 are configured to emit green light, and first light-emitting devices 124 of the blue sub-pixels B are configured to emit blue light. In this way, color display is achieved.

For example, with reference to FIGS. 6C and 6D, the first light-emitting devices 124 of the first sub-pixels P1′ are configured to emit white light. In this case, in conjunction with 6D, 7 and 8, the first sub-pixels P1′ further include a plurality of first filter portions 21. Each first filter portion 21 corresponds to a first opening region 151, and a border S1 of an orthographic projection of the first filter portion 21 on the substrate 11 (in conjunction with FIG. 6A) is located within an orthographic projection of the corresponding first light-shielding portion 15 on the substrate 11 (in conjunction with FIG. 6A). In this way, light from first light-emitting devices 124 is filtered, while the first light-shielding portion 15 is prevented from affecting light acquisition of the functional device 300 (in conjunction with FIG. 2). The plurality of first filter portions 21 may respectively transmit different monochromatic light, and the white light emitted from the first light-emitting devices 124 of the first sub-pixels P1′ is irradiated on corresponding first filter portions 21, so that monochromatic light of corresponding colors exits, and then full-color display is achieved.

For example, as shown in FIGS. 6C and 6D, the plurality of first sub-pixels P1′ includes the red sub-pixels R, the first green sub-pixels G1, the second green sub-pixels G2 and the blue sub-pixels B. First filter portions 21 of the red sub-pixels R may transmit red light, first filter portions 21 of the first green sub-pixels G1 and first filter portions 21 of the second green sub-pixels G2 may transmit green light, and first filter portions 21 of the blue sub-pixels B may transmit blue light. In this case, the white light emitted from the first light-emitting devices 124 of the red sub-pixels R, the first green sub-pixels G1, the second green sub-pixels G2 and the blue sub-pixels B is irradiated on the corresponding first filter portions 21, so that monochromatic light of corresponding colors exits, and then full-color display is achieved.

In addition, since the first filter portions 21 transmit monochromatic light, light of most wavelength bands in the external ambient light may be filtered out by the first filter portions 21. Therefore, the reflection intensity of the external ambient light in the functional device configuration region A1 of the display panel 200 may further reduced.

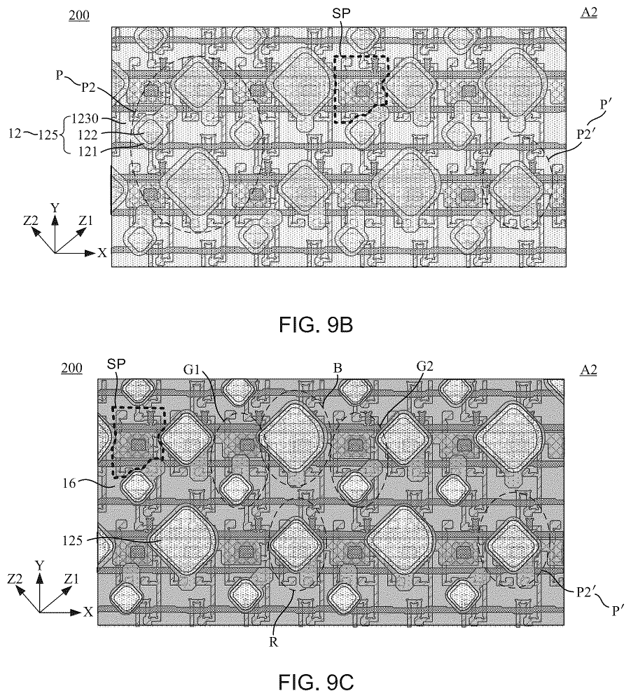

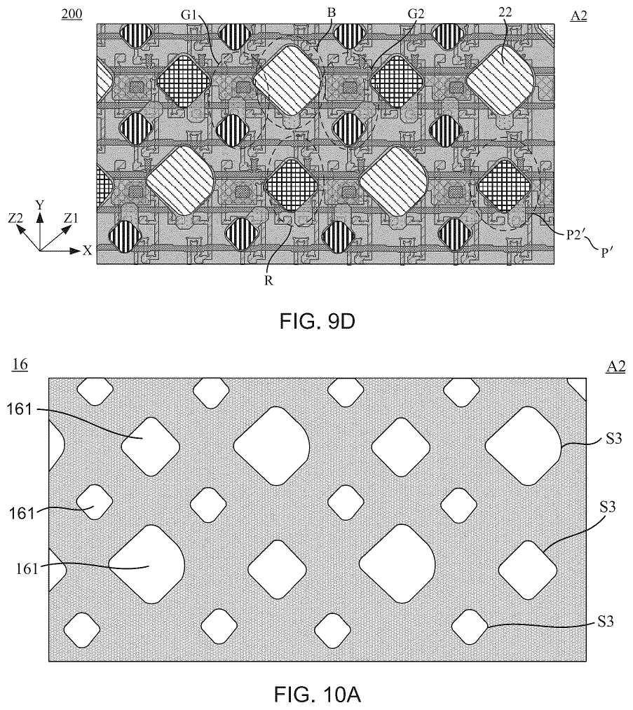

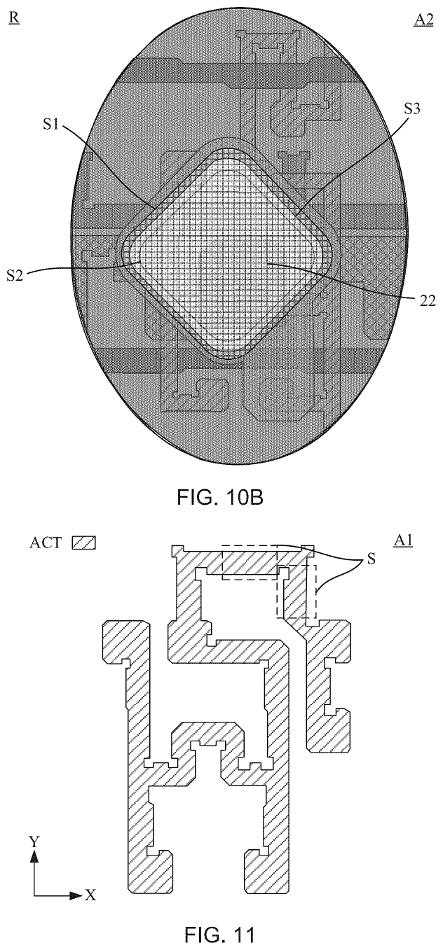

FIGS. 9A to 9D are top views of the main display region of the display panel in accordance with some embodiments. FIG. 10A is a structural diagram of a second light-shielding portion of the display panel in accordance with some embodiments. FIG. 10B is an enlarged view of a single red sub-pixel in the main display region of the display panel in accordance with some embodiments.

In conjunction with FIGS. 9A to 9D, the display panel 200 further includes a second light-shielding portion 16 located in the main display region A2. The second light-shielding portion 16 is disposed on a side of a plurality of second sub-pixels P2′ away from the substrate 11.

It will be noted that, the second light-shielding portion 16 may be made of a same material and disposed in a same layer as the first light-shielding portions 15.

With reference to FIGS. 9C and 10A, the second light-shielding portion 16 includes a plurality of third opening regions 161. Each third opening region 161 corresponds to a second light-emitting device 125, and a light-emitting region of the second light-emitting device 125 is located within the third opening region 161.

In conjunction with FIGS. 9A to 9D, orthographic projections of second portions SP of the second pixel circuits 136 on the substrate 11 are located within an orthographic projection of the second light-shielding portion 16 on the substrate 11. The second portions SP are portions, whose orthographic projections on the substrate 11 are located outside orthographic projections of third electrodes 121 on the substrate 11, of the second pixel circuits 136.

It will be noted that, in order to distinguish first electrodes 121 of the second light-emitting devices 125 from the first electrodes 121 of the first light-emitting devices 124, the first electrodes 121 of the second light-emitting devices 125 are referred to as third electrodes 121 herein. That is, the second light-emitting devices 125 include the third electrodes 121, and the third electrodes 121 are electrically connected to the second pixel circuits 136.

In this case, in the main display region A2, the orthographic projections of the second portions SP of the second pixel circuits 136 on the substrate 11 are located within the orthographic projection of the second light-shielding portion 136 on the substrate 11. That is to say, the orthographic projections of the second pixel circuits 136 on the substrate 11 are located in a range defined by orthographic projections of the third electrodes 121 and the orthographic projection of the second light-shielding portion 136 on the substrate 11. In this way, the external environment light may be prevented from directly irradiating on the second pixel circuits 136, which reduces reflection intensity of the external environment light in the main display region A2 of the display panel 200 and prevents a diffraction problem caused by external environment light directly irradiating on edges of the second pixel circuits 136, thereby improving the display effects. In addition, channel regions S of transistors 130 (e.g., first transistors T1) of the second pixel circuits 136 may be shielded by the third electrodes 121 and the second light-shielding portion 136, so that a drift risk of threshold voltages of the transistors 130 is reduced, which improves accuracy of driving currents and display effects in the main display region A2 of the display panel 200.

It will be understood that, the main display region A2 of the display panel 200 is only used for displaying images, and does not need to acquire the external ambient light. Thus, for the main display region A2 of the display panel 200, there is no need to consider a transmittance of a region between the second sub-pixels P2′. The lower the reflection intensity of the external ambient light is, the better the display effects are.

In view of this, with reference to FIGS. 9B to 9D, a first region is within the orthographic projection of the second light-shielding portion 16 on the substrate 11. The first region is a region between a plurality of second light-emitting devices 125 in the main display region A2. In this case, metal layers (e.g., the electrode layer 1230) in the region between the plurality of second light-emitting devices 125 can all be shielded by the second light-shielding portion 16, so that the reflection intensity of the external ambient light in the main display region A2 of the display panel 200 is reduced, and the display effects of the main display region A2 are improved.

On this basis, a portion of the electrode layer 1230 located in the main display region A2 may have a continuous film structure. This means that, the portion of the electrode layer 1230 located in the main display region A2 may not be subjected to a patterning process. That is, the region of the electrode layer 1230 located between the plurality of second sub-pixels P2′ may not be provided with light-transmitting holes, which simplifies a process.

In addition, since the first region is located within the orthographic projection of the second light-shielding portion 16 on the substrate 11, i.e., the region between the second light-emitting devices 125 of the second sub-pixel P2′, distances between centers of second light-emitting devices 125 of multiple second sub-pixels P2′ of a same second pixel unit P2 does not need to be shortened. That is, the plurality of second light-emitting devices 125 are arranged evenly.

For example, with reference to FIGS. 9B to 9D, in the main display region A2, a plurality of red sub-pixels R and a plurality of first green sub-pixels G1 are alternately arranged in the first oblique direction Z1, and the plurality of red sub-pixels R and a plurality of second green sub-pixels G2 are alternately arranged in the second oblique direction Z2; blue sub-pixels B and the second green sub-pixels G2 are alternately arranged in the first oblique direction Z1, and the blue sub-pixels B and the plurality of first green sub-pixels G1 are alternately arranged in the second oblique direction Z2; the first green sub-pixels G1 and the second green sub-pixels G2 are alternately arranged in the first direction X; and the red sub-pixels R and the blue sub-pixels B are alternately arranged in the second direction Y.

On this basis, in a setting direction, distances between centers of second light-emitting devices 125 of adjacent second sub-pixels P2′ are substantially equal. The setting direction may be any one of the first direction X, the second direction Y, the first oblique direction Z1 and the second oblique direction Z2.

It will be understood that, with reference to FIG. 9B, the second light-emitting devices 125 of the second sub-pixels P2′ may be configured to emit white light or colored light.

For example, with reference to FIG. 9C, the second light-emitting devices 125 of the second sub-pixels P2′ are configured to emit colored light. The colored light directly exits to the outside of the display panel 200.

For example, as shown in FIG. 9C, the plurality of second sub-pixels P2′ includes the red sub-pixels R, the first green sub-pixels G1, the second green sub-pixels G2 and the blue sub-pixels B. Second light-emitting devices 125 of the red sub-pixel R are configured to emit red light, second light-emitting devices 125 of the first green sub-pixels G1 and second light-emitting devices 125 of the second green sub-pixels G2 are configured to emit green light, and second light-emitting devices 125 of the blue sub-pixels B are configured to emit blue light. In this way, color display is achieved.

For example, in conjunction with FIGS. 9C and 9D, the second light-emitting devices 125 of the second sub-pixels P2′ are configured to emit white light. In this case, as shown in FIG. 9D, the second sub-pixels P2′ further include a plurality of second filter portions 22. In conjunction with FIGS. 9D, 10A and 10B, each second filter portion 22 corresponds to a third opening region 161, and borders S1 of orthographic projections of the second filter portions 22 on the substrate 11 are located within the orthographic projection of the second light-shielding portion 16 on the substrate 11 (in conjunction with FIG. 9A) In this way, light from the second light-emitting devices 125 are filtered. The plurality of second filter portions 22 may respectively transmit different monochromatic light. The white light emitted from the second light-emitting devices 125 of the second sub-pixels P2′ is irradiated on respective second filter portions 22, and then monochromatic lights of respective colors exits, so that full-color display is achieved.

For example, as shown in FIGS. 9C and 9D, the plurality of second sub-pixels P2′ include the red sub-pixels R, the first green sub-pixels G1, the second green sub-pixels G2 and the blue sub-pixels B. Second filter portions 22 of the red sub-pixels R may transmit red light, second filter portions 22 of the first green sub-pixels G1 and second filter portions 22 of the second green sub-pixels G2 may transmit green light, and second filter portions 22 of the blue sub-pixels B may transmit blue light. In this case, the white light emitted from the second light-emitting devices 125 of the red sub-pixels R, the first green sub-pixels G1, the second green sub-pixels G2 and the blue sub-pixels B is irradiated on the respective second filter portions 22, and then monochromatic light of corresponding colors exits, so that full-color display is achieved.

In addition, since the second filter portions 22 transmit monochromatic light, light of most wavelength bands in the external ambient light may be filtered out by the second filter portion 22. Therefore, the reflection intensity of the external ambient light in the main display region A2 of the display panel 200 may further reduced.

With reference to FIGS. 6B, 6C, 9B and 9C, the plurality of first sub-pixels P1′ and the plurality of second sub-pixels P2′ both include red sub-pixels R, first green sub-pixels G1, second green sub-pixels G2 and blue sub-pixels B.

On this basis, in conjunction with FIG. 8, in the functional device configuration region A1, a distance between a border S2 of a light-emitting region of a red sub-pixel R and a corresponding inner border S3 of a corresponding first light-shielding portion 15, a distance between a border S2 of a light-emitting region of a first green sub-pixel G1 and a corresponding inner boundary S3 of a corresponding first light-shielding portion 15, a distance between a border S2 of a light-emitting region of a second green sub-pixel G2 and a corresponding inner boundary S3 of a corresponding first light-shielding portion 15, and a distance between a border S2 of a light-emitting region of a blue sub-pixel B and a corresponding inner boundary S3 of a corresponding first light-shielding portion 15 are substantially equal to each other. In this way, the problem of luminance non-uniformity or color cast in the functional device configuration region A1 is avoided, which improves the display effects of the display panel 200 in the functional device configuration region A1.

In conjunction with FIG. 10B, in the main display region A2, a distance between a border S2 of a light-emitting region of a red sub-pixel R and a corresponding inner border S3 of the second light-shielding portion 16, a distance between a border S2 of a light-emitting region of a first green sub-pixel G1 and a corresponding inner border S3 of the second light-shielding portion 16, a distance between a border S2 of a light-emitting region of a second green sub-pixel G2 and a corresponding inner border S3 of the second light-shielding portion 16, and a distance between a border S2 of a light-emitting region of a blue sub-pixel B and a corresponding inner border S3 of the second light-shielding portion 16 are substantially equal to each other. In this way, the problem of luminance non-uniformity or color cast in the main display region A2 is avoided, which improves the display effects of the display panel 200 in the main display region A2. Illustration is given in FIG. 10B by taking the red sub-pixel R as an example.

On this basis, the distance between the borders S2 of the light-emitting regions of the first sub-pixels P1′ and the respective inner borders S3 of the first light-shielding portions 15 in the functional device configuration region A1 is substantially equal to the distance between the borders S2 of the light-emitting regions of the second sub-pixels P2 and the respective inner borders S3 of the second light-shielding portion 16 in the main display region A2. In this way, a problem of luminance non-uniformity or color cast between the functional device configuration region A1 and the main display region A2 is avoided, which improves the display effects of the display panel 200.

It is noted that, a border S2 of a light-emitting region is a border of a respective opening region of the pixel defining layer 14 herein.

It will be understood that, with reference to FIGS. 3A, 6E and 24, the display panel 10 further includes a plurality of signal lines. The plurality of signal lines are electrically connected to the pixel circuits 13 (including the first pixel circuits 135 and the second pixel circuits 136). At least one signal line includes a signal trace and a transferring line. The signal trace is used for being connected to an external signal source. The transferring line is connected to a first pixel circuit 135. A portion, located in the functional device configuration region A1, of the signal trace is transparent, which improves the transmittance of the display panel 200 in the functional device configuration region A1.

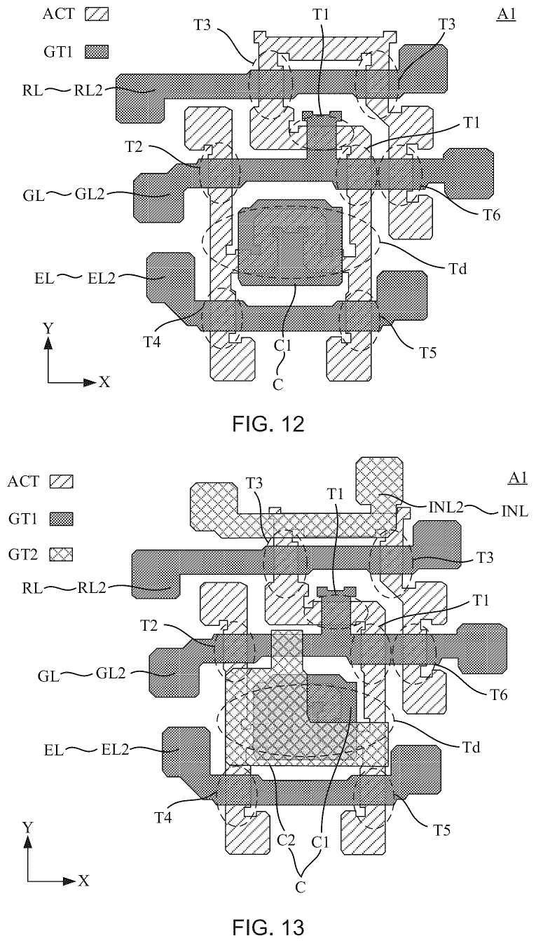

For example, with reference to FIGS. 3A, 12 16 and 19 to 24, the plurality of signal lines include scanning signal lines GL, reset signal lines RL, enable signal lines EL, initialization signal lines INL, first voltage signal lines VDL and data lines DL.

The scanning signal lines GL are electrically connected to scanning signal terminals GATE of the pixel circuits 13. The reset signal lines RL are electrically connected to reset signal terminals RESET of the pixel circuits 13. The enable signal lines EL are electrically connected to enable signal terminals EM of the pixel circuits 13. The initialization signal lines INL are electrically connected to initialization signal terminals VINIT of the pixel circuits 13. The first voltage signal lines VDL are electrically connected to first voltage signal terminals VDD of the pixel circuits 13. The data lines DL are electrically connected to data signal terminals DATA of the pixel circuits 13.

In some embodiments, with reference to FIGS. 6E, 12, 17 and 19, the scanning signal lines GL include first scanning traces GL1 and first transferring lines GL2. The first transferring lines GL2 extend substantially in the first direction X, and are electrically connected to the first pixel circuits 135. At least an end of each first scanning trace GL1 is located in the functional device configuration region A1, so that the first scanning traces GL1 are electrically connected to the first transferring lines GL2, which avoids interference between the scanning signal lines GL and some other signal line(s) (e.g., data lines DATA) due to wiring crossover.

On this basis, in the functional device configuration region A1, portions, located in the functional device configuration region A1, of the first scanning traces GL1 are transparent, which improves the transmittance of the display panel 200 in the functional device configuration region A1.

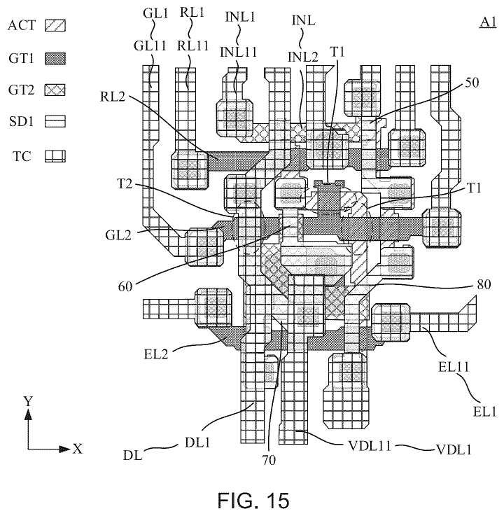

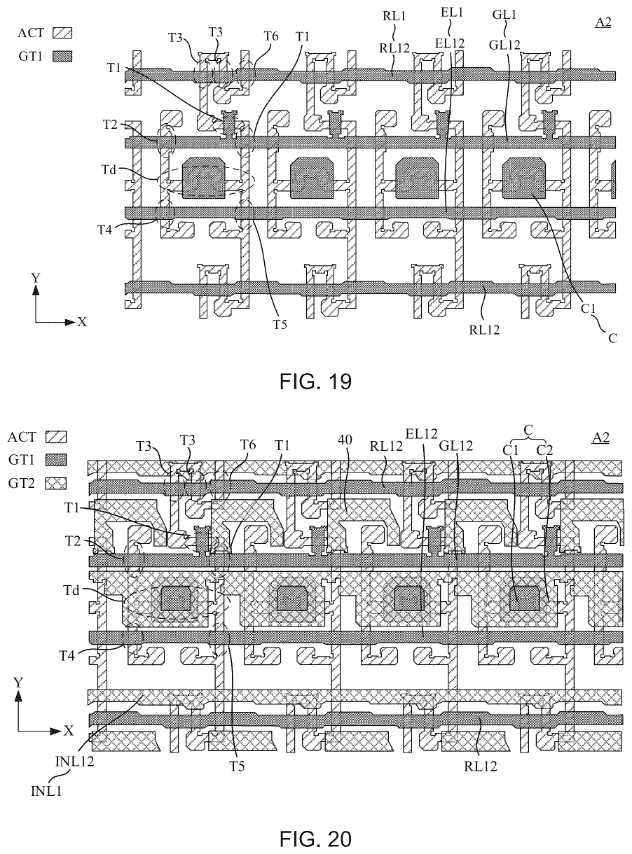

For example, as shown in FIGS. 15 and 19, the first scanning traces GL1 include first scanning sub-traces GL11 and second scanning sub-traces GL12. The first scanning sub-traces GL11 are located in the functional device configuration region A1. The second scanning sub-traces GL12 are located in the main display region A2. The first scanning sub-traces GL11 are transparent. The second scanning sub-traces GL12 may be transparent or opaque.

In some embodiments, with reference to FIGS. 6E, 12, 15 and 19, the reset signal lines RL include first reset traces RL1 and second transferring lines RL2. The second transferring lines RL2 extend substantially in the first direction X, and are electrically connected to the first pixel circuits 135. At least an end of each first reset trace RL1 is located in the functional device configuration region A1, so that the first reset traces RL1 are electrically connected to the second transferring lines RL2, which avoids interference between the reset signal lines RL and some other signal lines (e.g., the data lines DATA) due to wiring crossover.

On this basis, in the functional device configuration region A1, portions, located in the functional device configuration region A1, of the first reset traces RL1 are transparent, which improves the transmittance of the display panel 200 in the functional device configuration region A1.

For example, as shown in FIGS. 15 and 19, the first reset traces RL1 include first reset sub-traces RL11 and second reset sub-traces RL12. The first reset sub-traces RL11 are located in the functional device configuration region A1. The second reset sub-traces RL12 are located in the main display region A2. The first reset sub-traces RL11 are transparent. The second reset sub-traces RL12 may be transparent or opaque.

In some embodiments, with reference to FIGS. 6E, 12, 15 and 19, the enable signal lines EL include first enable traces EL1 and third transferring lines EL2. The third transferring lines EL2 extend substantially in the first direction X, and are electrically connected to the first pixel circuits 135. At least an end of each first enable trace EL1 is located in the functional device configuration region A1, so that the first enable traces EL1 are electrically connected to the third transferring lines EL2, which avoids interference between the enable signal lines EL and some other signal lines (e.g., the data lines DATA) due to wiring crossover.

On this basis, in the functional device configuration region A1, portions, located in the functional device configuration region A1, of the first enable traces EL1 are transparent, which improves the transmittance of the display panel 200 in the functional device configuration region A1.

For example, as shown in FIGS. 15 and 19, the first enabled traces EL1 include first enabled sub-traces EL11 and second enabled sub-traces EL12. The first enabled sub-traces EL11 are located in functional device configuration region A1. The second enabled sub-traces EL12 are located in main display region A2. The first enable sub-traces EL11 are transparent. The second enable sub-traces EL12 may be transparent or opaque.

In some embodiments, with reference to FIGS. 6E, 13, 15 and 20, the initialization signal lines INL include first initialization traces INL1 and fourth transferring lines INL2. The fourth transferring lines INL2 extend substantially in the first direction X, and are electrically connected to the first pixel circuits 135. At least an end of each first initialization trace INL1 is located in the functional device configuration region A1, so that the first initialization traces INL1 are electrically connected to the fourth transferring lines INL2, which avoids interference between the initialization signal lines INL and some other signal lines (e.g., the data lines DATA) due to wiring crossover.

On this basis, in the functional device configuration region A1, portions, located in the functional device configuration region A1, of the first initialization traces INL1 are transparent, which improves the transmittance of the display panel 200 in the functional device configuration region A1.

For example, as shown in FIGS. 15 and 20, the first initialization traces INL1 include first initialization sub-traces INL11 and second initialization sub-traces INL12. The first initialization sub-traces INL11 are located in the functional device configuration region A1. The second initialization sub-traces INL12 are located in the main display region A2. The first initialization sub-traces INL11 are transparent. The second initialization sub-traces INL12 may be transparent or opaque.

In some embodiments, with reference to FIGS. 6E, 16 and 23, the first voltage signal lines VDL and the data lines DL substantially extend in the first direction X. In the functional device configuration region A1, at least portions, located in the functional device configuration region A1, of the first voltage signal lines VDL and at least portions, located in the functional device configuration region A1, of the data lines DL are transparent, which improves the transmittance of the display panel 200 in the functional device configuration region A1.

For example, as shown in FIGS. 6E, 16 and 23, the first voltage signal lines VDL include first voltage traces VDL1 and fifth transferring lines VDL2. The fifth transferring lines VDL2 are disposed on a side of the first pixel circuits 135 away from the substrate 11, and electrically connected to the first voltage traces VDL1. That is to say, the fifth transferring lines VDL2 cross over the first pixel circuits 135 (in conjunction with FIG. 6A). In this case, when the first voltage signal lines VDL pass over the first pixel circuits 135, a distance between the first voltage signal lines VDL and the first pixel circuits 135 may be increased by means of the fifth transferring lines VDL2, so that electromagnetic interference is reduced.

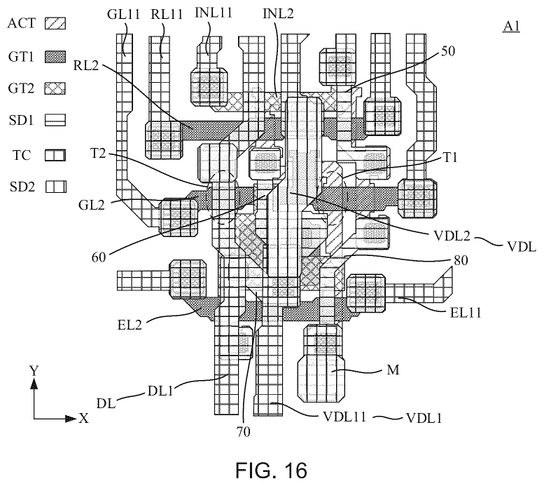

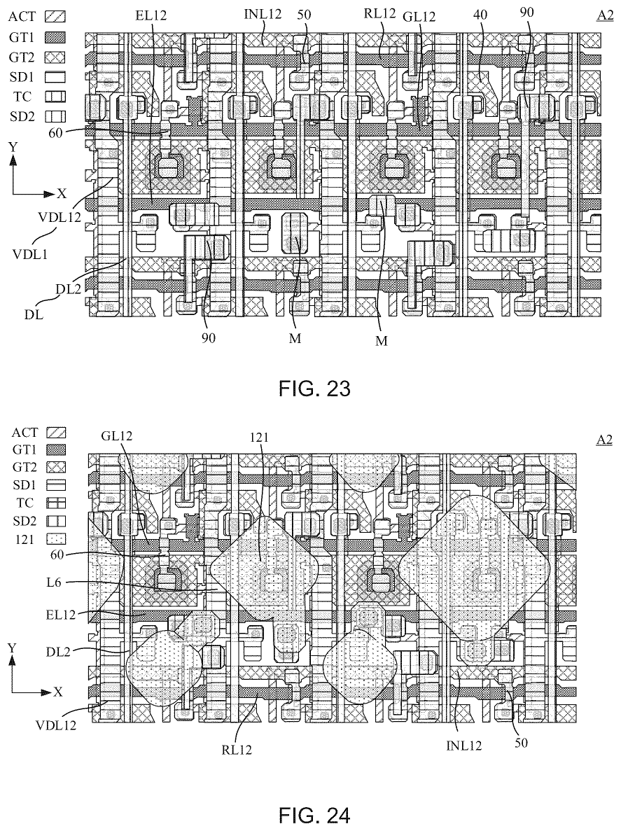

On this basis, as shown in FIGS. 16 and 23, the first voltage traces VDL1 may further include first voltage sub-traces VDL11 and second voltage sub-traces VDL12. The first voltage sub-traces VDL11 are located in the functional device configuration region A1. The second voltage sub-traces VDL12 are located in the main display region A2. The data lines DL include first data sub-lines DL1 and second data sub-lines DL2. The first data sub-lines DL1 are located in the functional device configuration region A1. The second data sub-lines DL2 are located in the main display region A2. Both the first voltage sub-traces VDL11 and the first data sub-lines DL1 may be transparent.

The signal lines included in film layers and some other patterned film layers are exemplarily described below in conjunction with a film layer structure of the display substrate 10.

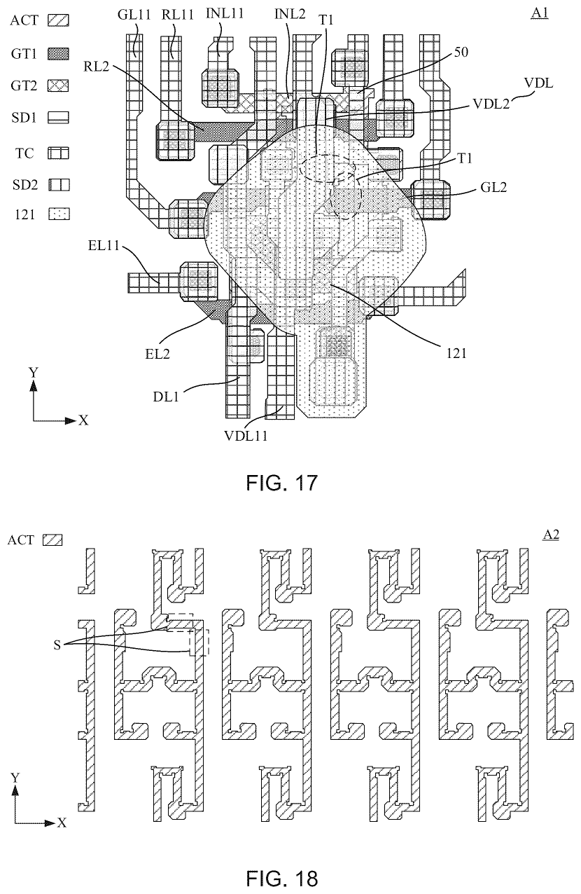

As shown in FIGS. 17 and 24, the display substrate 10 includes a semiconductor layer ACT, a first gate conductive layer GT1, a second gate conductive layer GT2, a first source-drain conductive layer SD1, a transparent conductive layer TC and a second source-drain conductive layer SD2 that are sequentially disposed in the direction perpendicular to and away from the substrate 11.

It will be noted that, an insulating film layer is disposed between any two adjacent layers of the semiconductor layer ACT, the first gate conductive layer GT1, the second gate conductive layer GT2, the first source-drain conductive layer SD1, the transparent conductive layer TC and the second source-drain conductive layer SD2. For example, with reference to FIGS. 3A and 3B, insulating film layers include a first gate insulating layer GI1, a second gate insulating layer GI2, an interlayer insulating layer ILD, a first planarization layer PLN1, a second planarization layer PLN2 and a planarization flat layer PLN3, which is not specifically limited in embodiments of the present disclosure.

As shown in FIGS. 3A, 3B, 11 and 18, the semiconductor layer ACT includes channel regions S of the transistors 130 of the pixel circuits 13.

It will be noted that, a material of the semiconductor layer ACT includes amorphous silicon, monocrystalline silicon, polycrystalline silicon or a metal oxide semiconductor material. For example, the material of the semiconductor layer ACT includes indium gallium zinc oxide (IGZO) or zinc oxide (ZnO), and embodiments of the present disclosure are not limited thereto.

As shown in FIGS. 12 and 19, the first gate conductive layer GT1 includes the first transferring lines GL2, the second transferring lines RL2, the third transferring lines EL2, the second scanning sub-traces GL12, the second reset sub-traces RL12, the second enable sub-traces EL12 and first electrode plates C1 of storage capacitors C. That is, the first transferring lines GL2, the second transferring lines RL2, the third transferring lines EL2, the second scanning sub-traces GL12, the second reset sub-traces RL12, the second enable sub-traces EL12 and the first electrode plates C1 of the storage capacitors C are located in a same layer, i.e., the first gate conductive layer GT1.

It will be noted that, a material of the first gate conductive layer GT1 includes metal. For example, the material of the first gate conductive layer GT1 includes at least one of aluminum, copper or molybdenum, and embodiments of the present disclosure are not limited thereto. That is to say, materials of the first transferring lines GL2, the second transferring lines RL2, the third transferring lines EL2 and the first electrode plates C1 of the storage capacitors C include metal.

With reference to FIG. 12, portions, overlapping with the semiconductor layer ACT, of the first transferring lines GL2 form control electrodes of first transistors T1, control electrodes of second transistors T2 and control electrodes of sixth transistors T6. Portions, overlapping with the semiconductor layer ACT, of the second transferring lines RL2 form control electrodes of third transistors T3. Portions, overlapping with the semiconductor layer, of the third transferring lines EL2 form control electrodes of fourth transistors T4 and control electrodes of fifth transistors T5. First electrode plates C1 of storage capacitors C located in the functional device configuration region A1 are located between respective first transferring lines GL2 and respective third transferring lines EL2.

In addition, with reference to FIG. 19, portions, overlapping with the semiconductor layer ACT, of the second reset sub-traces RL12 form control electrodes of third transistors T3 and control electrodes of sixth transistors T6; portions, overlapping with the semiconductor layer ACT, of the second scan sub-traces GL12 form control electrodes of first transistors T1 and control electrodes of second transistors T2; and portions, overlapping with the semiconductor layer ACT, of the second enable sub-traces EL12 form control electrodes of fourth transistor T4 and control electrodes of fifth transistor T5. First electrode plates C1 of storage capacitors C located in the main display A2 are located between respective second scanning sub-traces GL12 and respective second enable sub-traces EL12.

As shown in FIGS. 13 and 20, the second gate conductive layer GT2 includes the fourth transferring lines INL2, the second initialization sub-traces INL12 and second electrode plates C2 of the storage capacitors C. Orthographic projections of the second electrode plates C2 on the substrate 11 partially overlap with orthographic projections of respective first electrode plates C1 on the substrate 11.

It will be noted that, a material of the second gate conductive layer GT2 includes metal. For example, the material of the second gate conductive layer GT2 includes at least one of aluminum, copper or molybdenum, and embodiments of the present disclosure are not limited thereto.

With reference to FIGS. 13 and 20, the storage capacitors C are formed in regions where the orthographic projections of the second electrode plates C2 on the substrate 11 overlaps with the orthographic projections of the first electrode plates C1 on the substrate 11. The fourth transferring lines INL2 are electrically connected to the third transistors T3 and the sixth transistor T6 of the first pixel circuits 135 through connection lines. The second initialization sub-traces INL12 are electrically connected to the third transistors T3 and the sixth transistors T6 of the second pixel circuits 136 through connection lines.

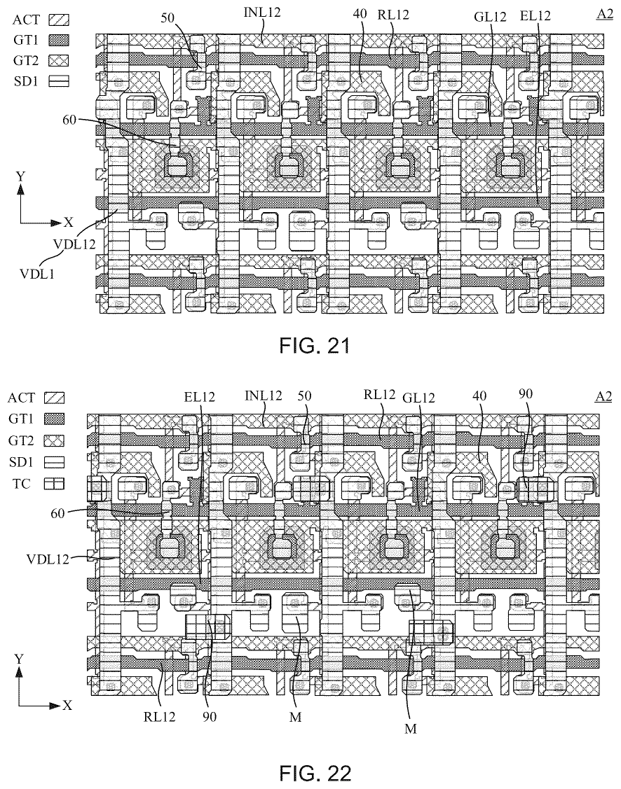

In some embodiments, with reference to FIGS. 20 and 21, the second gate conductive layer GT2 further includes shielding patterns 40 located in the main display region A2. The shield patterns 40 are located between the second reset sub-traces RL12 and the second scanning sub-traces GL12. Orthographic projections of the shielding patterns 40 on the substrate 11 are at least partially overlapped with orthographic projections of respective second voltage sub-traces VDL12 on the substrate 11, and the shielding patterns 40 are electrically connected with the second voltage sub-traces VDL12, so that electromagnetic interference between lines are reduced.

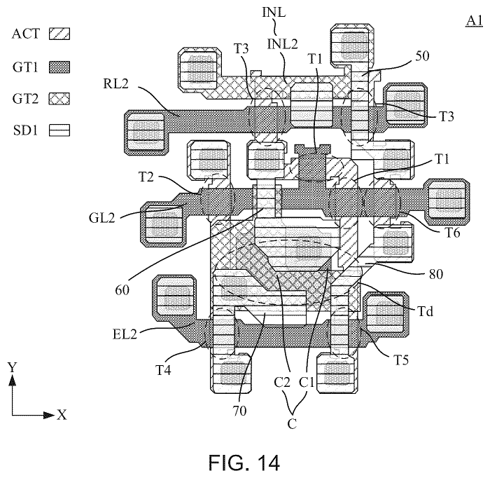

As shown in FIGS. 14 and 21, the first source-drain conductive layer SD1 includes sources 131 and drains 132 of the transistors 130, first connection lines 50, second connection lines 60, third connection lines 70, fourth connection lines 80 and the second voltage sub-traces VDL12. The first connection lines 50 and the second connection lines 60 are distributed in both the functional device configuration region A1 and the main display region A2. The third connection lines 70 and the fourth connection lines 80 are distributed only in the functional device configuration region A1.

It will be noted that, a material of the first source-drain conductive layer SD includes metal. For example, the material of the first source-drain conductive layer SD includes at least one of aluminum, copper or molybdenum, and embodiments of the present disclosure is not limited thereto.

In the functional device configuration region A1, in conjunction with FIGS. 13 and 14, a first connection line 50 is connected to a first electrode of a respective third transistor T3 and a first electrode of a respective sixth transistor T6. A second connection line 60 is electrically connected to an electrode plate C1 of a respective capacitor C, a second electrode of a respective first transistor T1 and a second electrode of a respective third transistor T3. A third connection line 70 is electrically connected to a second electrode plate C2 of a respective storage capacitor C and a first electrode of a respective fourth transistor T4. A fourth connection line 80 is electrically connected to a second electrode of a respective fifth transistor T5 and a second electrode of a respective sixth transistor T6.

In the main display region A2, in conjunction with FIGS. 20 and 21, first connection lines 50 are connected to first electrodes of respective third transistors T3 and first electrodes of respective sixth transistors T6. Second connection lines 60 are electrically connected to electrode plates C1 of respective storage capacitors C, second electrodes of respective first transistors T1 and second electrodes of respective third transistors T3.

In conjunction with FIGS. 15 and 22, at least the portions, located in the functional device configuration region A1, of the first scanning traces GL1, the first reset traces RL1, the first enable traces EL1, the first initialization traces INL1, the data lines DL and the first voltage signal lines VDL are transparent.

For example, as shown in FIGS. 15 and 22, the transparent conductive layer TC includes the first scanning sub-traces GL11, the first reset sub-traces RL11, the first enable sub-traces EL11, the first initialization sub-traces INL11, the first voltage sub-traces VDL11 and the first data sub-lines DL1.

It will be noted that, a material of the transparent conductive layer TC includes a transparent conductive material. A transmittance of the transparent conductive layer TC made of the transparent conductive material is greater than or equal to 60%. For example, the material of the transparent conductive layer TC includes indium tin oxide, and embodiments of the present disclosure are not limited thereto.

As shown in FIGS. 16 and 23, both the fifth transferring lines VDL2 and the second data sub-lines DL2 may be located in the second source-drain conductive layer SD2.

It will be noted that, a material of the second source-drain conductive layer SD includes metal. For example, the material of the second source-drain conductive layer SD2 includes at least one of aluminum, copper or molybdenum, and embodiments of the present disclosure are not limited thereto.

In addition, with reference to FIG. 23, the second source-drain conductive layer SD2 may further include support patterns 90 located in the main display region A2. The support patterns 90 and the second data sub-lines DL2 are parallel to each other, and disposed on two sides of respective second pixel circuits 136, so as to play a role in supporting and balancing first electrodes 121 of light-emitting devices 12. In addition, the support patterns 90 may be electrically connected to the second voltage sub-traces VDL12, so that the electromagnetic interference between signal lines may be further reduced.

Based on the above, with reference to FIGS. 16 and 23, pads M of the pixel circuits 13 may be composed of one or more layers of welding patterns formed in the first source-drain conductive layer SD1, the transparent conductive layer TC and the second source-drain conductive layer SD2. For example, with reference to FIGS. 14 to 16 and 21 to 23, the pads M are formed by sequentially stacking the welding patterns in the first source-drain conductive layer SD1, welding patterns in the transparent conductive layer TC and welding patterns in the second source-drain conductive layer SD2.

The foregoing descriptions are merely specific implementations of the present disclosure. However, the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, having a functional device configuration region, the display panel comprising:
a substrate;
a plurality of first sub-pixels, disposed on the substrate and located in the functional device configuration region, wherein at least some of the plurality of first sub-pixels each include a first pixel circuit and a first light-emitting device; the first light-emitting device includes a first electrode; the first electrode is electrically connected with the first pixel circuit; and an orthographic projection of a portion of the first pixel circuit on the substrate is located outside an orthographic projection of the first electrode on the substrate; and
a plurality of first light-shielding portions, arranged on a side of a plurality of first light-emitting devices of the at least some of the plurality of first sub-pixels away from the substrate at intervals and located in the functional device configuration region, wherein each first light-shielding portion is provided with a plurality of first opening regions; each first opening region corresponds to a single first light-emitting device of the plurality of first light-emitting devices, a light-emitting region of the single first light-emitting device is located in the first opening region, and an orthographic projection of a first portion of a first pixel circuit electrically connected with a first electrode of the single first light-emitting device on the substrate is located within an orthographic projection of the first light-shielding portion on the substrate, the first portion being a portion, whose orthographic projection on the substrate is located outside an orthographic projection of the first electrode on the substrate, of the first pixel circuit.

2. The display panel according to claim 1, wherein the display panel comprises a plurality of first pixel units disposed in the functional device configuration region; each first pixel unit includes multiple first sub-pixels of the plurality of first sub-pixels; and the plurality of first opening regions of each first slight-shielding portion correspond to multiple first sub-pixels of a same first pixel unit of the plurality of first pixel units in a one-to-one manner.

3. The display panel according to claim 1, wherein for multiple first sub-pixels located within an outer border of a same first light-shielding portion, a distance between centers of two first sub-pixels that are adjacent to each other in a setting direction is a first distance;
in the setting direction, a distance between centers of two adjacent first sub-pixels, which are respectively located within outer borders of two adjacent first light-shielding portions, is a second distance; and
the first distance is less than the second distance.

4. The display panel according to claim 3, wherein the plurality of first sub-pixels include a plurality of red sub-pixels, a plurality of first green sub-pixels, a plurality of second green sub-pixels and a plurality of blue sub-pixels; and
the plurality of red sub-pixels and the plurality of first green sub-pixels are alternately arranged in a first oblique direction, and the plurality of red sub-pixels and the plurality of second green sub-pixels are alternately arranged in a second oblique direction; the plurality of blue sub-pixels and the plurality of second green sub-pixels are alternately arranged in the first oblique direction, and the plurality of blue sub-pixels and the plurality of first green sub-pixels are alternately arranged in the second oblique direction; the plurality of first green sub-pixels and the plurality of second green sub-pixels are alternately arranged in a first direction; and the plurality of red sub-pixels and the plurality of blue sub-pixels are alternately arranged in a second direction, wherein
the first direction is perpendicular to the second direction; the first oblique direction intersects the second oblique direction; both the first oblique direction and the second oblique direction intersect each of the first direction and the second direction; or
the first direction is perpendicular to the second direction; the first oblique direction intersects the second oblique direction; both the first oblique direction and the second oblique direction intersect each of the first direction and the second direction; and the setting direction is any one of the first direction, the second direction, the first oblique direction and the second oblique direction.

5. (canceled)

6. The display panel according to claim 4, wherein the display panel comprises a plurality of first pixel units; and each first pixel unit includes a red sub-pixel, a first green sub-pixel, a second green sub-pixel and a blue sub-pixel that are adjacent to each other;
for a same first pixel unit, a red sub-pixel and a blue sub-pixel are arranged in the second direction, and a first green sub-pixel and a second green sub-pixel are arranged in the first direction; and
an outer border of an orthographic projection of a first light-shielding portion of the plurality of first light-shielding portions on the substrate is in a shape of an approximate rhombus.

7. The display panel according to claim 1, wherein the plurality of first light-shielding portions are arranged in a plurality of rows and a plurality of columns, each row includes multiple first light-shielding portions arranged in a first direction, and each column includes multiple first light-shielding portions arranged in a second direction, the first direction being perpendicular to the second direction.

8. The display panel according to claim 1, further comprising:
an electrode layer, disposed between first electrodes of the at least some of the plurality of first sub-pixels and the plurality of first light-shielding portions, wherein a portion, located in the functional device configuration region, of the electrode layer is provided with a plurality of second opening regions; and at least a portion of orthographic projections of the plurality of second opening regions on the substrate are located in a region between orthographic projections of the plurality of first light-shielding portions on the substrate.

9. The display panel according to claim 8, wherein the plurality of first light-shielding portions are arranged in a plurality of rows and a plurality of columns; and each row includes multiple first light-shielding portions arranged in a first direction, and each column includes multiple first light-shielding portions arranged in a second direction, the first direction being perpendicular to the second direction; and
two adjacent first light-shielding portions in the first direction are provided therebetween with a second opening region; and/or two adjacent first light-shielding portions in the second direction are provided therebetween with a second opening region.

10. The display panel according to claim 9, wherein multiple first light-shielding portions in a row are arranged to be staggered with multiple first light-shielding portions in another row adjacent thereto; and multiple first light-shielding portions in a column are arranged to be staggered with multiple first light-shielding portions in another column adjacent thereto.

11. (canceled)

12. The display panel according to claim 1, wherein the display panel further has a main display region, and the main display region at least partially surrounds the functional device configuration region; and the display panel further comprises:
a plurality of second sub-pixels, disposed on the substrate and located in the main display region, wherein each second sub-pixel includes a second pixel circuit and a second light-emitting device; at least some of a plurality of second light-emitting devices of the plurality of second sub-pixels each include a third electrode; the third electrode is electrically connected with a second pixel circuit of a plurality of second pixel circuits of the plurality of second sub-pixels, and an orthographic projection of a portion of the second pixel circuit on the substrate is located outside an orthographic projection of the third electrode on the substrate; and
a second light-shielding portion, disposed on a side of the plurality of second sub-pixels away from the substrate and located in the main display region, wherein the second light-shielding portion includes a plurality of third opening regions; each third opening region corresponds to a single second light-emitting device of the plurality of second light-emitting devices, and a light-emitting region of the single second light-emitting device is located in the third opening region; and orthographic projections of second portions of a plurality of second pixel circuits electrically connected to third electrodes of the at least some of the plurality of second devices on the substrate are located within an orthographic projection of the second light-shielding portion on the substrate, the second portions being portions, whose orthographic projections on the substrate are located outside orthographic projections of the third electrodes on the substrate, of the second pixel circuits.

13. The display panel according to claim 12, wherein a first region is within the orthographic projection of the second light-shielding portion on the substrate, the first region being a region between the plurality of second light-emitting devices in the main display region.

14. The display panel according to claim 12, further comprising:
an electrode layer, disposed between first electrodes of the at least some of the plurality of first sub-pixels and the plurality of first light-shielding portions, wherein a portion, located in the functional device configuration region, of the electrode layer is provided with a plurality of second opening regions; and at least a portion of orthographic projections of the plurality of second opening regions on the substrate are located in a region between orthographic projections of the plurality of first light-shielding portions on the substrate,
wherein a portion, located in the main display region, of the electrode layer has a continuous film layer structure.

15. (canceled)

16. The display panel according to claim 1, wherein the plurality of first sub-pixels further include:
a plurality of first filter portions, each first filter portion corresponding to a single first opening region of a first light-shielding portion of the plurality of first light-shielding portions, a border of an orthographic projection of the first filter portion on the substrate being located within an orthographic projection of the first light-shielding portion on the substrate; and
in a case where the display panel further comprises a plurality of second sub-pixels and a second light-shielding portion, the plurality of second sub-pixels further include:
a plurality of second filter portions, each second filter portion corresponding to a single third opening region of the second light-shielding portion, a border of an orthographic projection of the second filter portion on the substrate being within an orthographic projection of the second light-shielding portion on the substrate.

17. The display panel according to claim 1, further comprising:
an encapsulation layer disposed between the plurality of first light-shielding portions and the plurality of first light-emitting devices; and/or
a plurality of signal lines electrically connected to first pixel circuits of the at least some of the plurality of first sub-pixels, wherein at least one signal line includes a signal trace and a transferring line; the signal trace is used for being connected with an external signal source; the transferring line is connected with a first pixel circuit of the first pixel circuits; and a portion, located in the functional device configuration region, of the signal trace is transparent.

18. (canceled)

19. The display panel according to claim 17, wherein in a case where the display panel further comprises the plurality of signal lines, the plurality of signal lines include:
scanning signal lines, including first scanning traces and first transferring lines, wherein the first transferring lines extend in a first direction, and are electrically connected with the first pixel circuits; at least an end of each first scanning trace is located in the functional device configuration region so that the first scanning traces are electrically connected with the first transferring lines; and portions, located in the functional device configuration region, of the first scanning traces are transparent;
reset signal lines, including first reset traces and second transferring lines, wherein the second transferring lines extend in the first direction, and are electrically connected with the first pixel circuits; at least an end of each first reset trace is located in the functional device configuration region so that the first reset traces are electrically connected with the second transferring lines; and portions, located in the functional device configuration region, of the first reset traces are transparent;
enable signal lines, including first enable traces and third transferring lines, wherein the third transferring lines extend in the first direction, and are electrically connected with the first pixel circuits; at least an end of each first enable trace is located in the functional device configuration region so that the first enable traces are electrically connected with the third transferring lines; and portions, located in the functional device configuration region, of the first enable traces are transparent; and
initialization signal lines, including first initialization traces and fourth transferring lines, wherein the fourth transferring lines extend in the first direction, and are electrically connected with the first pixel circuits; at least an end of each first initialization trace is located in the functional device configuration region so that the first initialization traces are electrically connected with the fourth transferring lines; and portions, located in the functional device configuration region, of the first initialization traces are transparent.

20. The display panel according to claim 19, wherein the display panel comprises a semiconductor layer, a first gate conductive layer, a second gate conductive layer, a source-drain conductive layer and a transparent conductive layer that are sequentially disposed in a direction perpendicular to and away from the substrate, and
the first transferring lines, the second transferring lines and the third transferring lines are located in the first gate conductive layer, and the fourth transferring lines are located in the second gate conductive layer; and/or the portions, located in the functional device configuration region, of the first scanning traces, the first reset traces, the first enable traces and the first initialization traces are located in the transparent conductive layer.

21. The display panel according to claim 17, wherein in a case where the display panel further comprises the plurality of signal lines, the plurality of signal lines further includes first voltage signal lines and data lines, the first voltage signal lines and the data lines extend in a second direction, and are both electrically connected to the first pixel circuits; and
at least portions, located in the functional device configuration region, of the first voltage signal lines and at least portions, located in the functional device configuration region, of the data lines are transparent.

22. The display panel according to claim 21, wherein the first voltage signal lines include first voltage traces and fifth transferring lines; and the fifth transferring lines are disposed on a side of the first pixel circuits away from the substrate, and electrically connected to the first voltage traces.

23. The display panel according to claim 22, wherein the display panel comprises a semiconductor layer, a first gate conductive layer, a second gate conductive layer, a source-drain conductive layer, a transparent conductive layer and a second source-drain conductive layer that are sequentially disposed in a direction perpendicular to and away from the substrate; and
portions, located in the functional device configuration region, of the first voltage traces and the portions, located in the functional device configuration region, of the data lines are located in the transparent conductive layer, and the fifth transferring lines are located in the second source-drain conductive layer.

24. A display apparatus, comprising:
a housing; and
the display panel according to claim 1, the display panel being disposed in the housing.
